(19) United States
(12) Patent Application Publication
(10) Pub. No.: US 2024/0321640 A1
(43) Pub. Date: Sep. 26, 2024

(54) Gate Patterning for Stacked Device Structure

(71) Applicant: Taiwan Semiconductor Manufacturing Company, Ltd., Hsin-Chu (TW)

(72) Inventors: Szu-Hua Chen, Tainan City (TW); Lilin Chang, Hsinchu (TW); Yahru Cheng, Taipei (TW); Wei-Yen Woon, Taoyuan City (TW); Szuya Liao, Zhubei Hsinchu (TW)

(21) Appl. No.: 18/404,831

(22) Filed: Jan. 4, 2024

Related U.S. Application Data
(60) Provisional application No. 63/492,007, filed on Mar. 24, 2023.

(51) Int. Cl. H01L 21/822; H01L 21/8238; H01L 27/092; H01L 29/06; H01L 29/423; H01L 29/49; H01L 29/66; H01L 29/775

(52) U.S. Cl. CPC H01L 21/8221; H01L 21/823807; H01L 21/823857; H01L 27/0922; H01L 29/0673; H01L 29/42392; H01L 29/4908; H01L 29/66439; H01L 29/66545; H01L 29/775

(57) ABSTRACT

A stacked channel structure includes a first channel structure having a first gate dielectric thereon, an isolation structure over the first channel structure, and a second channel structure over the isolation structure. The second channel structure has a second gate dielectric thereon. A method may include forming a dummy layer that has a top surface below the second channel structure, selectively depositing a hard mask over the second gate dielectric, selectively removing the dummy layer, and selectively removing the hard mask after the dummy layer. Deposition parameters and a composition of the dummy layer are configured to inhibit deposition of the hard mask on the dummy layer. A first gate electrode and a second gate electrode may be formed over the first gate dielectric and the second gate dielectric, respectively. The hard mask may be selectively removed before or after forming the first gate electrode.

This is a non-provisional application of and claims benefit of U.S. Provisional Patent Application Ser. No. 63/492,007, filed Mar. 24, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

As the semiconductor industry progresses into advanced IC technology nodes in pursuit of higher device density, higher performance, and lower costs, challenges from both a fabrication perspective and a design perspective have led to stacked transistor configurations, which have presented a new set of challenges. For example, vertically patterning gate layers of a lower gate of a lower, bottom transistor of a transistor stack without damaging gate layers of an upper gate of an upper, top transistor of the transistor stack, or vice versa, is difficult. Such patterning may be particularly difficult when the upper transistor and the lower transistor are different types, such as an n-type metal-oxide-semiconductor (NMOS) transistor over or under a p-type metal-oxide-semiconductor (PMOS) transistor. Improved gate patterning techniques for stacked device structures, such as complementary transistor stacks, are thus needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a cross-sectional view of a stacked device structure, in portion or entirety, according to various aspects of the present disclosure.

FIG. 1B and FIG. 1C are cross-sectional views of the stacked device structure of FIG. 1A, in portion or entirety, according to various aspects of the present disclosure.

FIG. 2 is a flow chart of a method for fabricating gate stacks of transistors of a stacked device structure, such as gate stacks of transistors of the stacked device structure of FIGS. 1A-IC, according to various aspects of the present disclosure.

FIGS. 3A-3P are cross-sectional views are a stacked device structure, such as the stacked device structure of FIGS. 1A-IC, in portion or entirety, at various fabrication stages associated with the method of FIG. 2 according to various aspects of the present disclosure.

FIG. 4 is a flow chart of another method for fabricating gate stacks of transistors of a stacked device structure, such as gate stacks of transistors of the stacked device structure of FIGS. 1A-1C, according to various aspects of the present disclosure.

### DETAILED DESCRIPTION

The present disclosure relates generally to stacked device structures, such as transistor stacks having n-type transistors and p-type transistors (i.e., complementary field effect transistors (CFETs)), and more particularly, to gate patterning techniques for stacked device structures.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for case of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Stacked transistor structures provide further density reduction for advanced integrated circuit (IC) technology nodes (particularly as they advance to 3 nm (N3) and below), especially when the stacked transistor structures include multigate devices, such as fin-like field effect transistors (FinFETs), gate-all-around (GAA) transistors including nanowires and/or nanosheets, other types of multigate devices, etc. Stacked transistor structures vertically stack transistors. For example, a transistor stack may include a first transistor (e.g., a top transistor) disposed over a second transistor (e.g., a bottom transistor). The transistor stack provides a complementary field effect transistor (CFET) when the first transistor and the second transistor are of opposite conductivity type (i.e., an n-type transistor and a p-type transistor).

An IC may include numerous transistor stacks. Providing the IC with transistors having multiple threshold voltages (Vt) can maximize its performance and/or reliability, for example, by boosting speed/performance of some transistors of the IC while reducing power consumption of other transistors of the IC. However, providing multigate devices with multiple threshold voltages is challenging because multigate devices are becoming very small, which leaves minimal room for tuning their threshold voltages using different work function metals. Dipole engineering may flexibly provide multigate devices with different threshold voltages by incorporating dipole dopants into gate dielectrics thereof and minimize and/or eliminate the need for using different work function metals. This may obviate the need of patterning work function metals, making dipole engineering very suitable for nano-sized transistors, such as FinFETs and GAA transistors. Although existing dipole engineering techniques have been generally adequate for their intended purposes, they have not been entirely satisfactory in all respects, particularly when implemented in the fabrication of stacked transistors, such as CFETs.

The present disclosure provides gate fabrication techniques, which include dipole engineering, that may realize multi-threshold voltage tuning for transistor stacks. According to various aspects of the present disclosure, a dummy layer and a hard mask layer are implemented during dipole engineering to facilitate introducing dipole dopant into a bottom gate dielectric of a bottom transistor without introducing such dipole dopant into a top gate dielectric of a top transistor. For example, after forming a dipole dopant source layer on the bottom gate dielectric and the top gate dielectric, processing may include forming the dummy layer over the bottom gate dielectric (e.g., by depositing and etching back a dummy material), removing the dipole dopant source layer from the top gate dielectric, selectively depositing the hard mask layer over the top gate dielectric, removing the dummy layer, and removing the hard mask layer before and/or after a thermal drive-in process for driving dopant from the dipole dopant source layer into the bottom gate dielectric. Compositions and formations of the dummy layer and the hard mask layer arc configured to inhibit formation of the hard mask layer on the dummy layer, such that the dummy layer may be removed without removing the hard mask layer. In some embodiments, the dummy layer is a spin-on dielectric material that includes silicon, oxygen, and terminal functional groups that inhibit formation of the hard mask layer on the dummy layer. In some embodiments, formation of the hard mask layer implements metal-containing precursors having metal compounds that include functional groups that do not adsorb on the dummy layer. The hard mask layer may thus protect the top gate dielectric during removal of the dummy layer (e.g., the top gate dielectric is not damaged by an etching process that may be used to remove the dummy layer), and a patterned dipole dopant source layer may be provided for adjusting characteristics of the bottom gate dielectric while preserving integrity of the top gate dielectric and/or top channel layer. The disclosed gate fabrication techniques may enable dipole engineering and vertical patterning (e.g., top/bottom patterning of a dipole dopant source layer and/or of gate electrodes) in stacked device structures with minimal to no increase in fabrication costs. Different embodiments may have different advantages, and no particular advantage is required of any embodiment. Details of improved gate stacks for transistors of stacked device structures and methods of fabrication and/or design thereof are described herein.

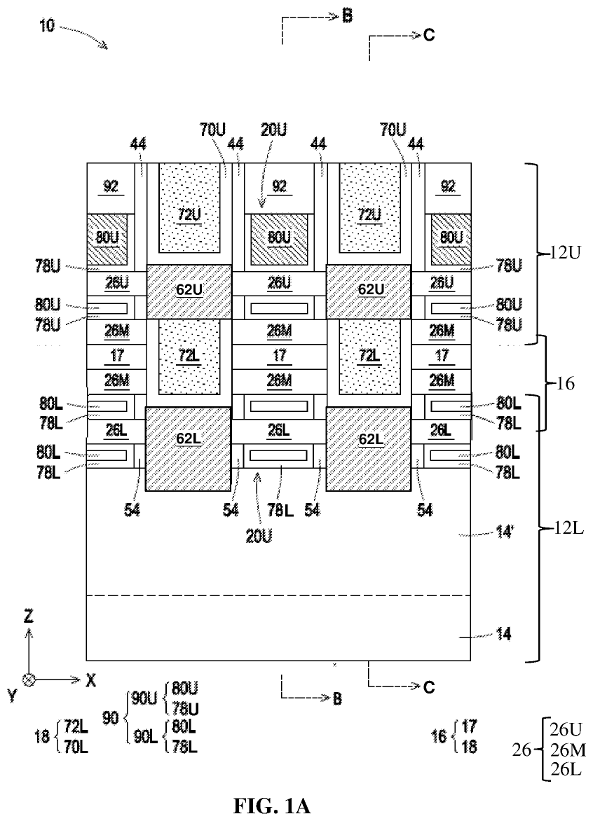

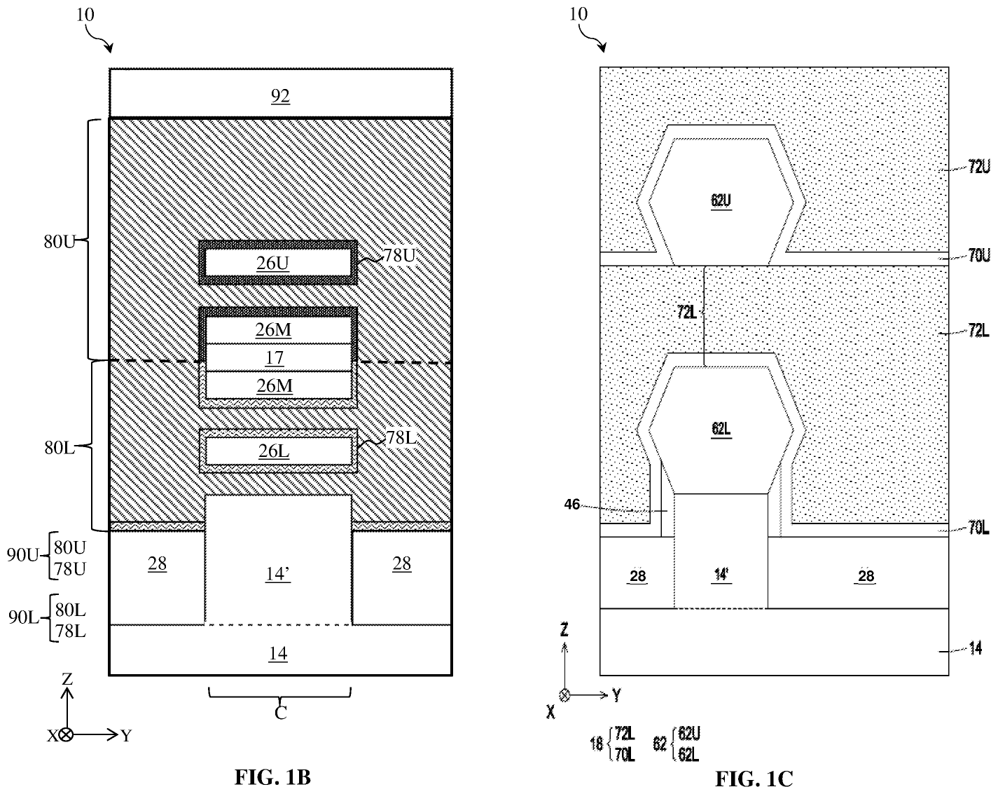

FIG. 1A is a cross-sectional view of a stacked device structure 10, in portion or entirety, according to various aspects of the present disclosure. FIG. 1B and FIG. 1C are cross-sectional views of stacked device structure 10, in portion or entirety, along line B-B and line C-C, respectively, of FIG. 1A according to various aspects of the present disclosure. Stacked device structure 10 includes upper devices 12U and lower devices 12L. A device stack of stacked device structure 10 may include a respective upper device 12U vertically stacked over a respective lower device 12L, which is disposed over a substrate 14. The device stack may further include an isolation structure 16 that is disposed between and separates device 12U and device 12L. Isolation structure 16 includes isolation structures 17 and insolation structures 18. In some embodiments, device 12U and device 12L are stacked back-to-front. In some embodiments, isolation structure 16 (e.g., isolation structures 17 thereof) may bond and/or attach a backside of device 12U to a frontside of device 12L, and isolation structure 16 may be referred to as a bonding layer/structure. In some embodiments, stacked device structure 10 is fabricated monolithically and may be referred to as a monolithic stacked device structure. In some embodiments, stacked device structure 10 is fabricated sequentially and may be referred to as a sequential stacked device structure. FIGS. 1A-IC has been simplified for the sake of clarity to better understand the inventive concepts of the present disclosure. Additional features may be added in stacked device structure 10, and some of the features described below may be replaced, modified, or eliminated in other embodiments of stacked device structure 10.

In FIGS. 1A-IC, devices 12U and devices 12L include at least one electrically functional device. For example, the device stack is a transistor stack having an upper transistor 20U (one of devices 12U) and a lower transistor 20L (one of devices 12L). Transistor 20U may be separated and/or electrically isolated from transistor 20L by isolation structure 16. In the depicted embodiment, transistor 20U and transistor 20L are of an opposite conductivity type. For example, transistor 20U is an n-type transistor, and transistor 20L is a p-type transistor. In another example, transistor 20U is a p-type transistor, and transistor 20L is an n-type transistor. In such embodiments, transistor 20U and transistor 20L form a CFET. In some embodiments, transistor 20U and transistor 20L are of a same conductivity type. For example, transistor 20U and transistor 20L are both n-type transistors or both p-type transistors.

Devices 12U include various features and/or components, such as semiconductor layers 26U, semiconductor layers 26M, gate spacers 44, inner spacers 54, epitaxial source/drains 62U, a contact etch stop layer (CESL) 70U, an interlayer dielectric (ILD) layer 72U, gate dielectrics 78U, gate electrodes 80U, and hard masks 92. Gate dielectric 78U and gate electrode 80U collectively form an upper gate stack 90U. Devices 12L include various features and/or components, such as mesas 14′ (e.g., extensions of substrate 14), semiconductor layers 26L, semiconductor layers 26M, substrate isolation structures 28, fin spacers 46, inner spacers 54, epitaxial source/drains 62L, a CESL 70L, an ILD layer 72L, gate dielectrics 78L, and gate electrodes 80L. Gate dielectric 78L and gate electrode 80L collectively form a lower gate stack 90L. Gate stack 90U and gate stack 90L are collectively referred to as a gate 90 (or gate stack) of the device stack 12B, and gate 90 may provide a metal gate or a high-k/metal gate of the second CFET. Gate stack 90U is separated from gate stack 90L by a respective isolation structure 17 (and semiconductor layers 26M, in the depicted embodiment), and epitaxial source/drains 62L are separated from epitaxial source/drains 62U by isolation structures 18.

Transistor 20L is configured as a GAA transistor. For example, transistor 20L has one channel (e.g., a nanowire, a nanosheet, a nanobars, etc.) provided by semiconductor layer 26L (also referred to as a channel layer or channel), which is suspended over substrate 14 and extends between respective source/drains, such as epitaxial source/drains 62L. In some embodiments, transistor 20L includes more or less channels (and thus more or less semiconductor layers 26L). Transistor 20L has gate stack 90L disposed over semiconductor layer 26L and between its epitaxial source/drains 62L. Along a gate widthwise direction (FIG. 1A), gate stack 90L is between semiconductor layer 26L and semiconductor 26M and between semiconductor layer 26L and substrate 14 (e.g., mesa 14′ thereof). Along a gate lengthwise direction (FIG. 1B and FIG. 1C), gate stack 90L wraps around semiconductor layer 26L. During operation of the GAA transistor, current may flow through semiconductor layer 26L and between respective epitaxial source/drains 62L. Transistor 20L further has a respective semiconductor layer 26M (also referred to as a dummy channel layer or dummy channel) suspended over substrate 14 and extending between respective isolation structures 18. Isolation structures 17 are disposed between semiconductor layers 26M of transistor 20L and semiconductor layers 26M of transistor 20U. Further, transistor 20L has inner spacers 54 disposed between gate stack 90L and its epitaxial source/drains 62L, and fin spacers 46 disposed along sidewalls of mesas 14′.

Transistor 20U is also configured as a GAA transistor. For example, transistor 20U has one channel (e.g., nanowires, nanosheets, nanobars, etc.) provided by semiconductor layer 26U (also referred to as a channel layer or channel), which is suspended over substrate 14 and extends between respective source/drains, such as epitaxial source/drains 62U. In some embodiments, transistor 20U includes more or less channels (and thus more or less semiconductor layers 26U). Transistor 20U has gate stack 90U disposed over semiconductor layer 26U and between epitaxial source/drains 62U. Along a gate widthwise direction (FIG. 1A), gate stack 90U is over semiconductor layer 26U and between semiconductor layer 26U and a respective semiconductor layer 26M. Along a gate lengthwise direction (FIG. 1B and FIG. 1C), gate stack 90U wraps around semiconductor layer 26U. During operation of the GAA transistor, current may flow through semiconductor layer 26U and between respective epitaxial source/drains 62U. Further, transistor 20U has gate spacers 44 disposed along sidewalls of an upper portion of gate stack 90L, inner spacers 54 disposed between gate stack 90L and epitaxial source/drains 62U, and a respective hard mask 92 disposed over gate stack 90L and between gate spacers 44. Hard mask 92 may be considered a portion of gate stack 90L.

Isolation structure 16 has isolation structures 17 and isolation structures 18 between channel regions and source/drain regions, respectively, of devices 12L and devices 12U. For example, isolation structures 17 are between channel regions of transistor 20L and channel regions of transistor 20U (e.g., between channels and/or gates thereof), and isolation structures 18 are between source/drain regions of transistor 20L and source/drain regions of transistor 20U. In the depicted embodiment, isolation structures 17 are between semiconductor layers 26M of transistor 20L and transistor 20U, and isolation structures 18 are between epitaxial source/drains 62L of transistor 20L and epitaxial source/drains 62U of transistor 20U. Accordingly, isolation structures 17 may provide electrical isolation of channels and/or gates of stacked devices, and isolation structures 18 may provide electrical isolation of source/drains of stacked devices. Isolation structures 17 and isolation structures 18 may include a single layer or multiple layers. Isolation structures 17 and isolation structures 18 include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). Isolation structures 17 and isolation structures 18 may include the same or different materials and/or configurations. In the depicted embodiment, a thickness of isolation structures 17 is less than a thickness of isolation structures 18, and a configuration of isolation structures 17 is different than a configuration of isolation structures 18. In some embodiments, isolation structures 18 include CESL 70L and ILD layer 72L, such as depicted (i.e., each isolation structure 18 is formed by a respective portion of CESL 70L and a respective portion of ILD layer 72L).

Substrate 14, semiconductor layer 26U, semiconductor layers 26M, and semiconductor layer 26L include an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, substrate 14 semiconductor layer 26U, semiconductor layers 26M, and semiconductor layer 26L include silicon. In some embodiments, semiconductor layer 26U and semiconductor layer 26L include different semiconductor materials, such as silicon and silicon germanium, respectively, or vice versa. In such embodiments, semiconductor layer 26M of transistor 20U and semiconductor layer 26M of transistor 20L may include different materials. In some embodiments, substrate 14 is a semiconductor-on-insulator substrate, such as a silicon-on-insulator substrate, a silicon germanium-on-insulator substrate, or a germanium-on-insulator substrate. Substrate 14 (including mesas 14′ extending therefrom) may include various doped regions, such as p-wells and n-wells. The n-wells are doped with n-type dopants, such as phosphorus, arsenic, other n-type dopant, or a combination thereof. The p-wells are doped with p-type dopants, such as boron, indium, other p-type dopant, or a combination thereof. In some embodiments, semiconductor layer 26U, semiconductor layers 26M, and semiconductor layer 26L, or a combination thereof include p-type dopants, n-type dopants, or a combination thereof. For case of description herein, semiconductor layer 26U, semiconductor layers 26M, and semiconductor layer 26L may be referred to collectively as semiconductor layers 26.

Substrate isolation structures 28 electrically isolate active device regions and/or passive device regions. For example, substrate isolation structures 28 separate and electrically isolate an active region of transistor 20L, such as mesa 14′ and/or epitaxial source/drains 62L thereof, from other device regions and/or devices. Substrate isolation structures 28 includes silicon oxide, silicon nitride, silicon oxynitride, other suitable isolation material (including, silicon, oxygen, nitrogen, carbon, other suitable isolation constituent, or a combination thereof), or a combination thereof. Substrate isolation structures 28 may have a multilayer structure. For example, substrate isolation structures 28 include a bulk dielectric (e.g., an oxide layer) over a dielectric liner (e.g., silicon nitride, silicon oxide, silicon oxynitride, silicon oxycarbonitride, or a combination thereof). In another example, substrate isolation structures 28 include a bulk dielectric over a doped liner, such as a boron silicate glass (BSG) liner and/or a phosphosilicate glass (PSG) liner. Dimensions and/or characteristics of substrate isolation structures 28 are configured to provide shallow trench isolation (STI) structures, deep trench isolation (DTI) structures, local oxidation of silicon (LOCOS) structures, other suitable isolation structures, or a combination hereof. In FIGS. 1A-1C, substrate isolation structures 28 may be STIs.

Gate spacers 44 are disposed along sidewalls of top portions of gate stack 90U, fin/mesa spacers 46 are disposed along sidewalls of mesas 14′, and inner spacers 54 are disposed under gate spacers 44 along sidewalls of gate stack 90U and gate stack 90L. Inner spacers 54 are between semiconductor layers 26U and semiconductor layers 26M, between semiconductor layers 26L and semiconductor layers 26M, and semiconductor layers 26L and mesas 14′. Gate spacers 44, fin spacers 46, and inner spacers 54 include a dielectric material. The dielectric material may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). Gate spacers 44, fin spacers 46, and inner spacers 54 may include different materials and/or different configurations (e.g., different numbers of layers). In some embodiments, gate spacers 44, fin spacers 46, inner spacers 54, or a combination thereof have a multilayer structure. In some embodiments, gate spacers 44 and/or fin spacers 46 include more than one set of spacers, such as seal spacers, offset spacers, sacrificial spacers, dummy spacers, main spacers, or a combination thereof. The various sets of spacers may have different compositions.

Gate 90 is disposed between respective epitaxial source/drain stacks. Each epitaxial source/drain stack includes a respective epitaxial source/drain 62U, a respective epitaxial source/drain 62L, and a respective insolation structure 18 therebetween. Epitaxial source/drains 62L and epitaxial source/drains 62U may be doped with n-type dopants and/or p-type dopants. In some embodiments, epitaxial source/drains 62L and/or epitaxial source/drains 62U include silicon doped with carbon, phosphorous, arsenic, other n-type dopant, or a combination thereof (e.g., Si:C epitaxial source/drains, Si:P epitaxial source/drains, or Si:C:P epitaxial source/drains). In some embodiments, epitaxial source/drains 62L and/or epitaxial source/drains 62U include silicon germanium or germanium, which is doped with boron, other p-type dopant, or a combination thereof (e.g., Si:Ge:B epitaxial source/drains). Epitaxial source/drains 62L and epitaxial source/drains 62U may have the same or different compositions and/or materials depending on configurations of their respective transistors. For example, in the depicted embodiment, transistor 20U is configured as an n-type transistor and transistor 20L is configured as a p-type transistor, epitaxial source/drains 62U may include silicon doped with phosphorous and/or carbon, and epitaxial source/drains 62L may include silicon germanium doped with boron. In some embodiments, epitaxial source/drains 62L and/or epitaxial source/drains 62U include more than one epitaxial semiconductor layer, and the epitaxial semiconductor layers may include the same or different materials and/or the same or different dopant concentrations. In some embodiments, epitaxial source/drains 62L and/or epitaxial source/drains 62U include materials and/or dopants that achieve desired tensile stress and/or compressive stress in adjacent channel regions (e.g., formed by semiconductor layers 26U and semiconductor layers 26L). As used herein, source/drain region, epitaxial source/drain, epitaxial source/drain feature, etc. may refer to a source of a device (e.g., transistor 20U or transistor 20L), a drain of a device (e.g., transistor 20U or transistor 20L), or a source and/or a drain of multiple devices.

ILD layer 72U and ILD layer 72L include a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or a combination thereof. In some embodiments, ILD layer 72U and/or ILD layer 72L include a dielectric material having a dielectric constant that is less than a dielectric constant of silicon dioxide (e.g., k<3.9). In some embodiments, ILD layer 72U and/or ILD layer 72L includes a dielectric material having a dielectric constant that is less than about 2.5 (i.e., an extreme low-k (ELK) dielectric material), such as porous silicon oxide, silicon carbide, carbon-doped oxide (e.g., an SiCOH-based material (having, for example, Si—CH₃ bonds)), or a combination thereof, each of which is tuned/configured to have a dielectric constant less than about 2.5. CESL 70L and CESL 70U include a dielectric material that is different than the dielectric material of ILD layer 72U and ILD layer 72L, respectively. For example, where ILD layer 72U and ILD layer 72L include a low-k dielectric material (e.g., porous silicon oxide), CESL 70L and CESL 70U may include silicon and nitrogen and/or carbon, such as silicon nitride, silicon carbonitride, or silicon oxycarbonitride. In some embodiments, CESL 70L and/or CESL 70U may include metal and oxygen, nitrogen, carbon, or a combination thereof. ILD layer 72U, ILD layer 72L CESL 70L, CESL 70U, or a combination thereof may have a multilayer structure.

Hard masks 92 include a material that is different than ILD layer 72U and/or subsequently formed ILD layers to achieve etch selectivity during subsequent etching processes. In some embodiments, hard masks 92 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or a combination thereof. In some embodiments, hard masks 92 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or a combination thereof.

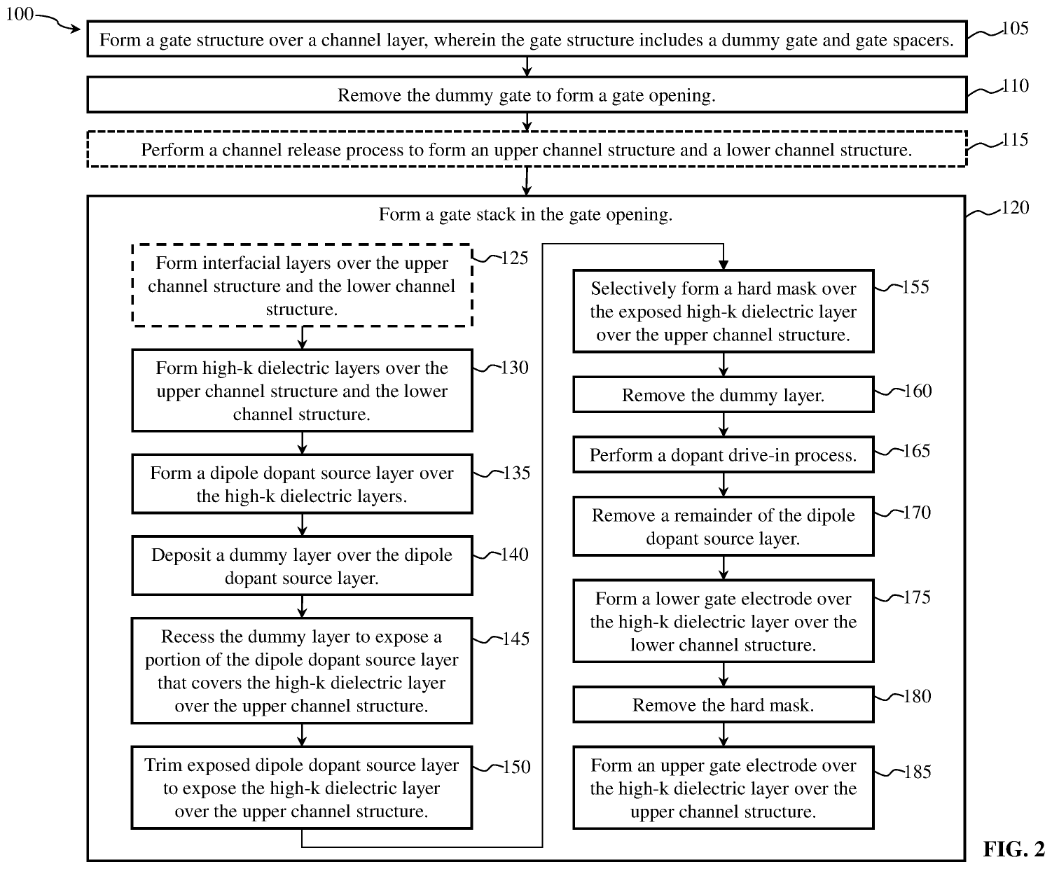

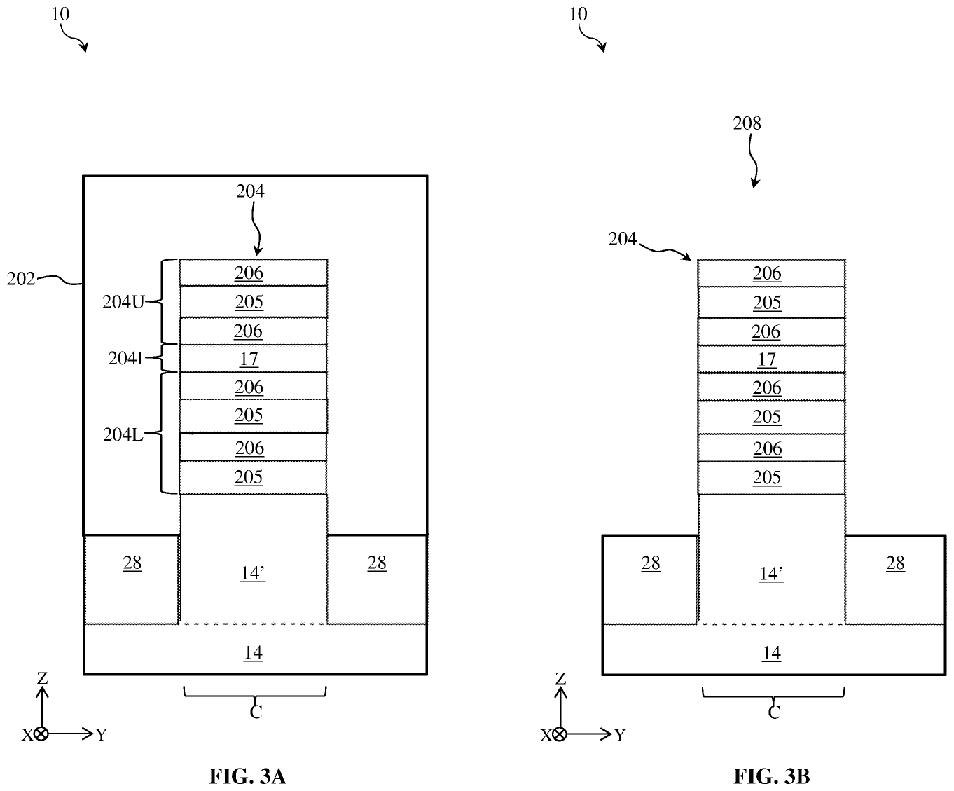

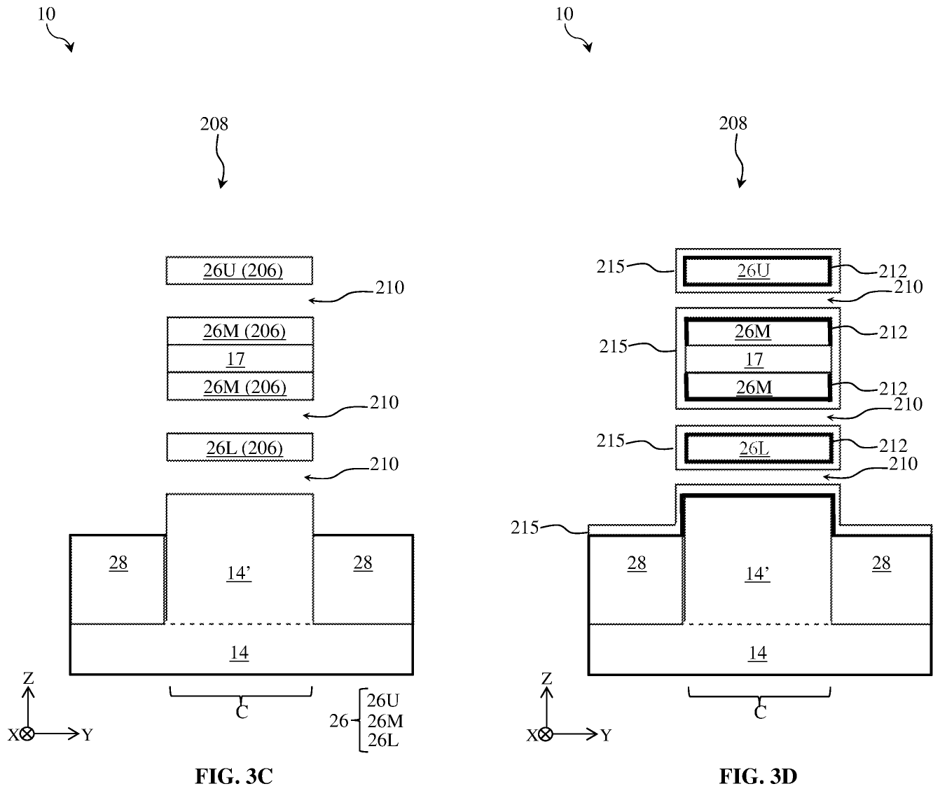

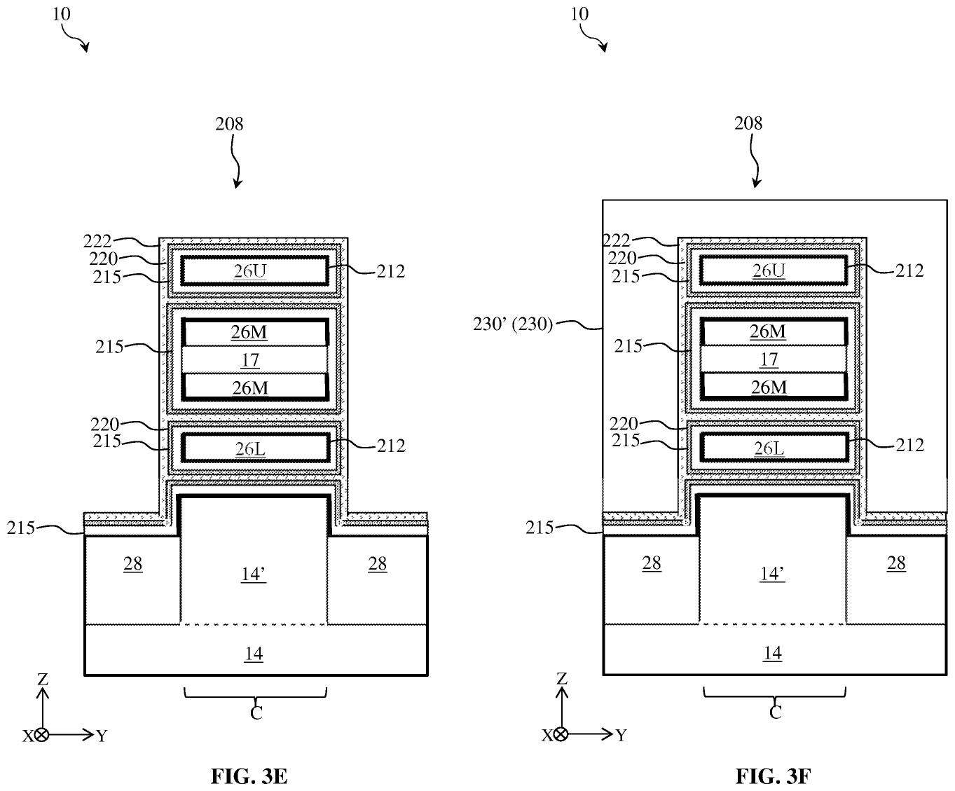

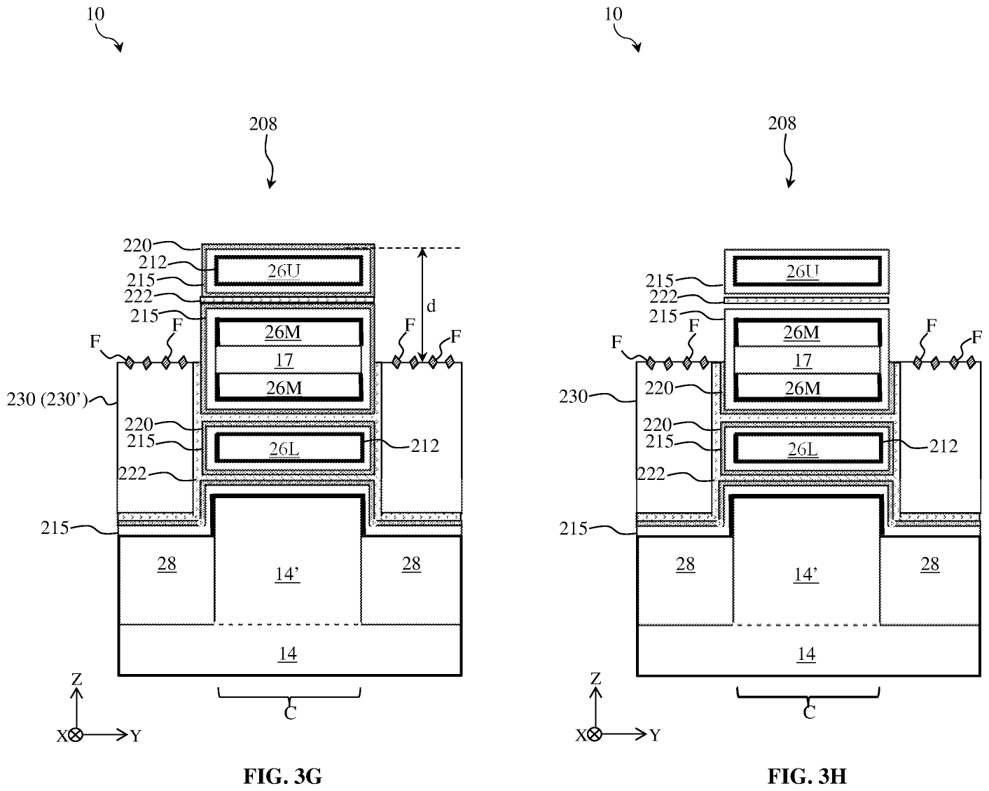

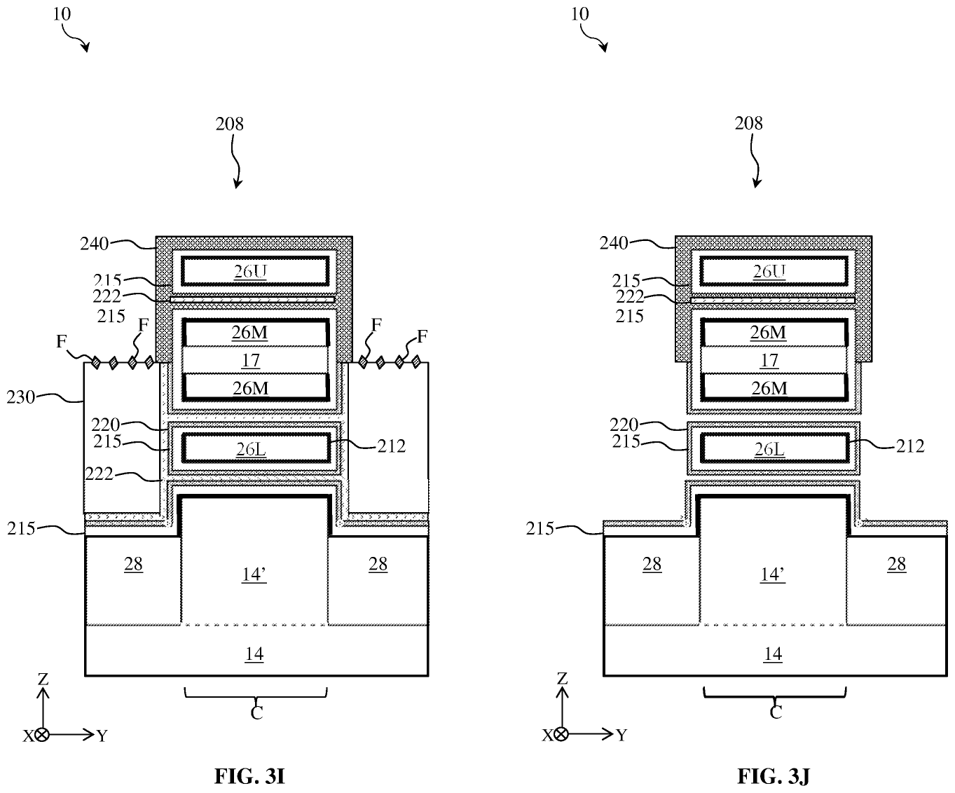

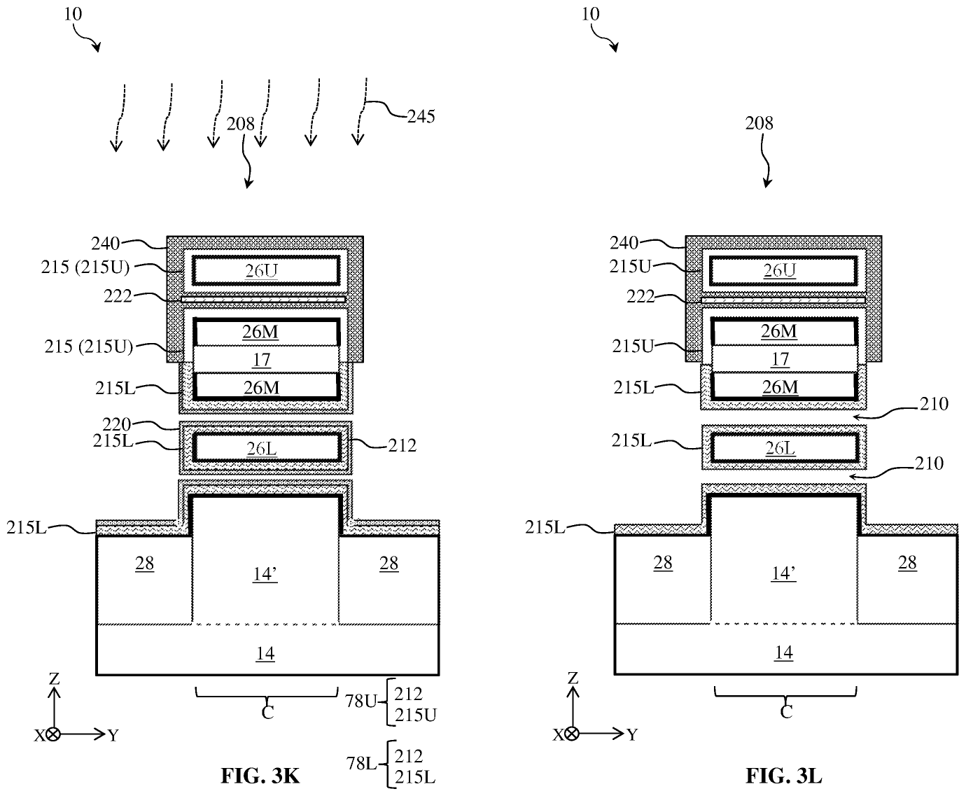

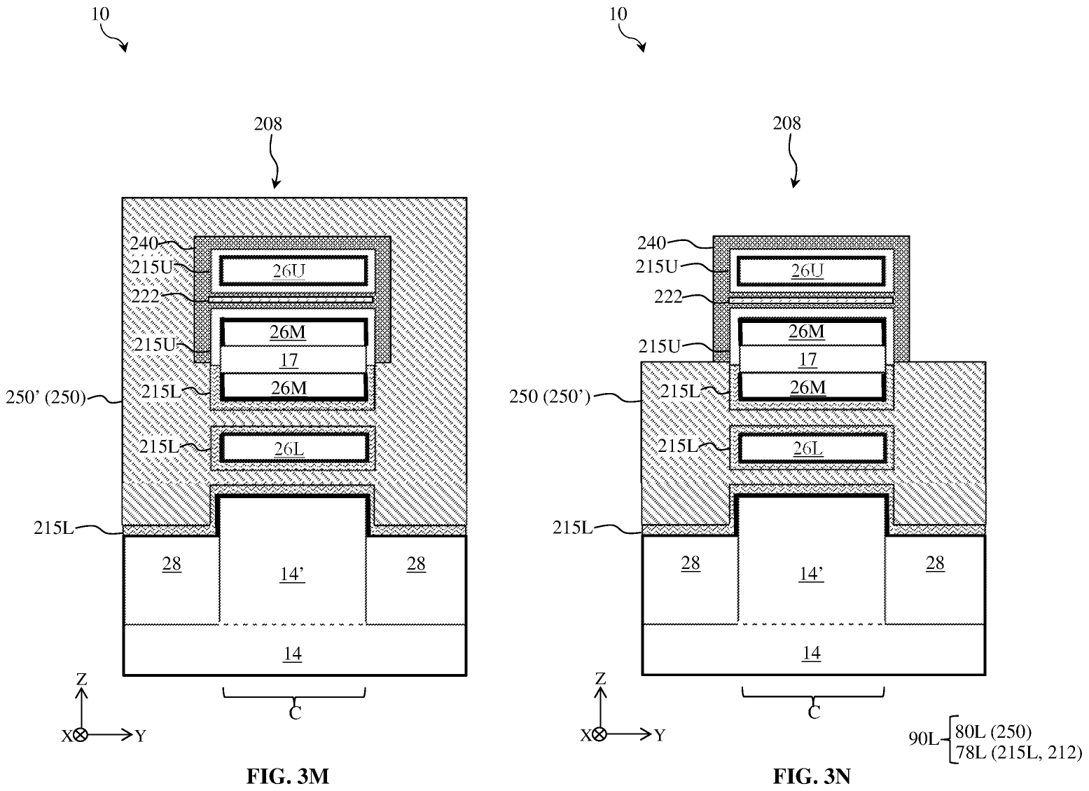

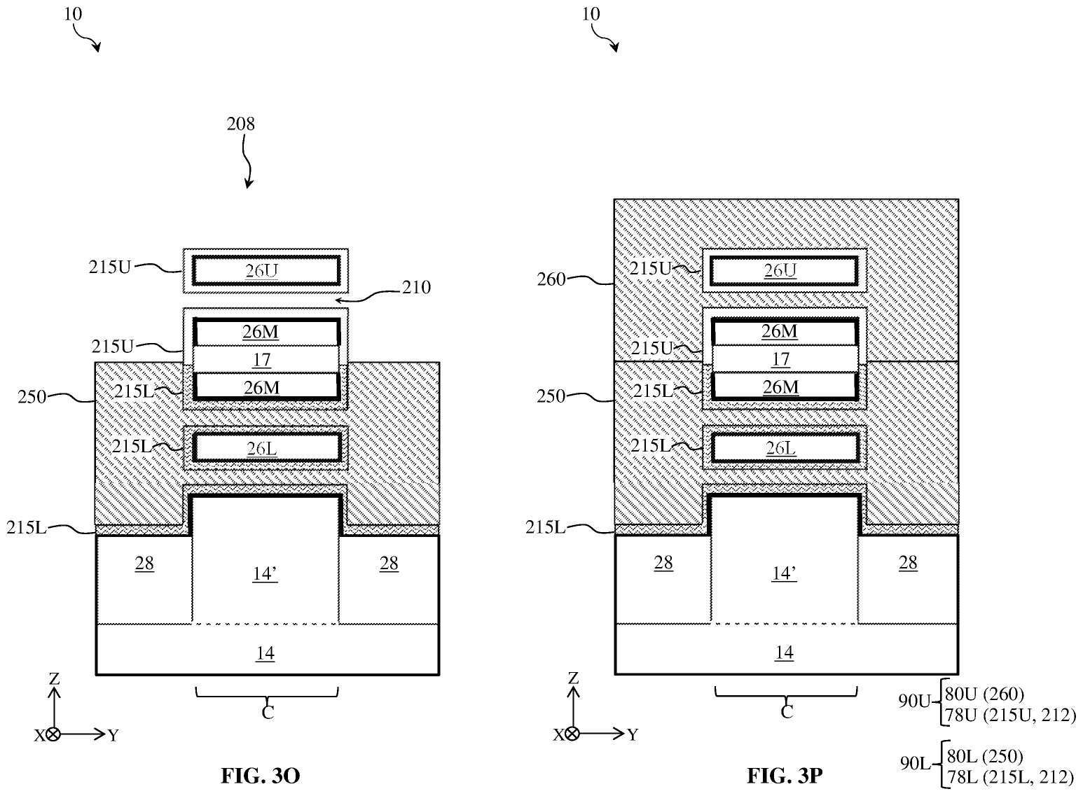

FIG. 2 is a flow chart of a method 100 for fabricating a gate stack of transistors of a transistor stack, such as gate 90 of the transistor stack of stacked device structure 10 of FIGS. 1A-IC, according to various aspects of the present disclosure. FIGS. 3A-3P are cross-sectional views of a stacked device structure, such as stacked device structure 10 of FIGS. 1A-1C, in portion or entirety, at various fabrication stages associated with method 100 of FIG. 2 according to various aspects of the present disclosure. Method 100 described with reference to FIGS. 2A-2J implements vertical gate patterning of stacked device structure, which may provide gate 90L and gate 90U with different configurations and may provide transistor 20U and transistor 20L with different threshold voltages. The disclosed vertical gate patterning technique may minimize and/or prevent damage to upper, top gate layers of gate 90U while forming and/or tuning lower, bottom gate layers of gate 90L. The cross-sectional views of FIGS. 3A-3P are taken (cut) along a gate lengthwise direction (e.g., a y-direction), like the cross-sectional view of FIG. 1B. FIG. 2 and FIGS. 3A-3P have been simplified for the sake of clarity to better understand the inventive concepts of the present disclosure. Additional steps can be provided before, during, and after method 100, and some of the steps described can be moved, replaced, or eliminated for additional embodiments of method 100. Additional features may be added in stacked device structure 10 of FIGS. 3A-3P, and some of the features described below can be replaced, modified, or eliminated in other embodiments of stacked device structure 10 of FIGS. 3A-3P.

Referring to FIG. 2 and FIG. 3A, method 100 at block 105 includes forming a gate structure (e.g., having a dummy gate 202 and gate spacers 44 (e.g., in an X—Z cross-sectional view)) over a semiconductor layer stack 204. The gate structure is disposed over semiconductor layer stack 204 and between epitaxial source/drains 62U, 62L. Dummy gate 202 extends along the y-direction, having a length along the y-direction, a width along the x-direction, and a height along the z-direction. Dummy gate 202 is disposed over a top and sidewalls of semiconductor layer stack 204, and dummy gate 202 wraps semiconductor layer stack 204. In the X—Z cross-sectional view, dummy gate 202 is disposed on a top of semiconductor layer stack 204, and gate spacers 44 are disposed along sidewalls of dummy gate 202. Dummy gate 202 may include a dummy gate electrode (e.g., a polysilicon layer) and a dummy gate dielectric (e.g., a silicon oxide layer). Dummy gate 202 may include additional layers, such as a hard mask layer. In some embodiments, a dielectric layer (e.g., CESL 70U and ILD layer 72U) is formed before or after forming the gate structure, and the gate structure is disposed in the dielectric layer.

Semiconductor layer stack 204 has an upper semiconductor stack 204U, an intermediate stack 2041, a lower semiconductor stack 204L, and mesa 14′. Semiconductor layer stack 204 extends lengthwise in a direction that is different than (e.g., orthogonal to) the lengthwise direction of dummy gate 202. For example, semiconductor layer stack 204 extends along the x-direction, having a length along the x-direction, a width along the y-direction, and a height along the z-direction. Upper semiconductor stack 204U and lower semiconductor stack 204L each include semiconductor layers 205 and semiconductor layers 206, and intermediate stack 2041 includes isolation structure 17. Semiconductor layer stack 204 may be a portion of a device precursor that is formed and/or received before forming the gate structure. The device precursor may also include isolation structures 18 (e.g., in the X—Z cross-sectional view), substrate isolation structures 28, fin spacers 46 (e.g., in a Y—Z cross-sectional view of source/drain regions), inner spacers 54 (e.g., in the X—Z cross-sectional view), epitaxial source/drains 62U (e.g., in the X—Z cross-sectional view), and epitaxial source/drains 62L (e.g., in the X—Z cross-sectional view). Semiconductor layer stack 204 is in a channel region C, and epitaxial source/drains 62U, 62L are in source/drain regions S/D. Along the x-direction, each semiconductor layer 206 extends between epitaxial source/drains 62U, isolation structures 18, or epitaxial source/drains 62L, mesa 14′ extends between epitaxial source/drains 62L, and inner spacers 54 are between semiconductor layers 205 and epitaxial source/drains 62U, 62L.

A composition of semiconductor layers 205 is different than a composition of semiconductor layers 206 to achieve etching selectivity and/or different oxidation rates during subsequent processing. For example, semiconductor layers 205 and semiconductor layers 206 include different materials, constituent atomic percentages, constituent weight percentages, thicknesses, or a combination thereof. For example, semiconductor layers 205 include silicon germanium, semiconductor layers 206 include silicon, and a silicon etch rate of semiconductor layers 206 is different than a silicon germanium etch rate of semiconductor layers 205 to a given etchant. In some embodiments, semiconductor layers 205 and semiconductor layers 206 include the same material but different constituent atomic percentages to achieve etching selectivity. For example, semiconductor layers 205 and semiconductor layers 206 include silicon germanium with different silicon atomic percentages and/or different germanium atomic percentages. In the depicted embodiment, semiconductor layers 206 of upper semiconductor stack 204U and lower semiconductor stack 204L have a same composition (e.g., silicon). In some embodiments, semiconductor layers 206 of upper semiconductor stack 204U and lower semiconductor stack 204L have different compositions. The present disclosure contemplates semiconductor layers 205 and semiconductor layers 206 including any combination of semiconductor materials that provides desired etching selectivity, desired oxidation rate differences, desired performance characteristics (e.g., materials that maximize current flow), or a combination thereof.

Referring to FIG. 2 and FIG. 3B, method 100 at block 110 includes removing dummy gate 202 to form a gate opening 208 that exposes semiconductor layer stack 204. Gate opening 208 has sidewalls formed by gate spacers 44 and a bottom formed by semiconductor layer stack 204 and/or substrate isolation structures 28. In some embodiments, an etching process selectively removes dummy gate 202 with respect to semiconductor layer stack 204, substrate isolation structures 28, gate spacers 44, the dielectric layer, or a combination thereof. For example, the etching process removes dummy gate 202 without (or negligibly) removing mesa 14′, semiconductor layers 205, semiconductor layers 206, isolation structure 17, gate spacers 44, substrate isolation structures 28, CESL 70U, and ILD layer 72U. The etching process is a dry etch, a wet etch, other suitable etch, or a combination thereof. In some embodiments, a patterned mask layer (an etch mask) is formed that exposes dummy gate 202 and covers CESL 70U, ILD layer 72U, gate spacers 44, or a combination thereof during the etching process.

Turning to FIG. 2 and FIG. 3C, method 100 at block 115 may include performing a channel release process. The channel release process may include selectively removing semiconductor layers 205 exposed by gate opening 208 to form gaps 210 between semiconductor layers 206 and between bottom semiconductor layer 206 and mesa 14′, thereby suspending semiconductor layers 206 in channel region C. In the depicted embodiment, four semiconductor layers 206 are vertically stacked along the z-direction and suspended over mesa 14′ after the channel release process. Top semiconductor layer 206 (of upper semiconductor stack 204U) may provide a channel through which current may flow between epitaxial source/drains 62U, and thus, may be referred to as semiconductor layer 26U, channel 26U, and/or an upper channel structure. Bottom semiconductor layer 206 (of lower semiconductor stack 204L) may provide a channel through which current may flow between epitaxial source/drains 62L, and thus, may be referred to as semiconductor layer 26L, channel 26L, and/or a lower channel structure. Middle semiconductor layers 206 (one of upper semiconductor stack 204U and one of lower semiconductor stack 204L) extend between isolation structures 18 and may not function as channels, and thus, may be referred to as semiconductor layers 26M and/or dummy channels 26M. Semiconductor layers 26M and isolation structure 17 combine to form an intermediate structure between the upper channel structure and the lower channel structure. In some embodiments, the intermediate structure includes only isolation structure 17. For ease of description and understanding, semiconductor layer 26U, semiconductor layer 26L, and semiconductor layers 26M may collectively be referred to as semiconductor layers 26. Further, the upper channel structure and lower channel structure having the intermediate structure therebetween may be referred to as a channel stack of stacked device structure 10.

In some embodiments, the channel release process includes an etching process that selectively etches semiconductor layers 205 without (or negligibly) etching semiconductor layers 206, mesa 14′, isolation structure 17, gate spacers 44, inner spacers 54, substrate isolation structures 28, the dielectric layer, or a combination thereof. An etchant may be selected for the etching process that etches silicon germanium (i.e., semiconductor layers 205) at a higher rate than silicon (i.e., semiconductor layers 206 and mesa 14′) and dielectric materials (i.e., the etchant has a high etch selectivity with respect to silicon germanium). The etching process is a dry etch, a wet etch, other suitable etching process, or a combination thereof. In some embodiments, before the etching process, an oxidation process converts semiconductor layers 205 into semiconductor oxide features (e.g., silicon germanium oxide), and the etching process then removes the semiconductor oxide features. In some embodiments, during and/or after removing semiconductor layers 205, an etching process is performed to modify a profile of semiconductor layers 206 to achieve target dimensions and/or target shapes of semiconductor layers 206, such as cylindrical-shaped channel layers (e.g., nanowires), rectangular-shaped channel layers (e.g., nanobars), sheet-shaped channel layers (e.g., nanosheets), etc.

Referring to FIG. 2 and FIG. 3D, method 100 at block 125 includes forming interfacial layers 212 over the upper channel structure (e.g., semiconductor layer 26U) and the lower channel structure (e.g., semiconductor layers 26M). Interfacial layers 212 partially fill gate opening 208 and gaps 210. Interfacial layers 212 are formed by thermal oxidation, chemical oxidation, atomic layer deposition (ALD), chemical vapor deposition (CVD), other suitable process, or a combination thereof. In the depicted embodiment, interfacial layers 212 form on semiconductor surfaces (e.g., semiconductor layers 206), but not dielectric surfaces (e.g., substrate isolation structures 28 and/or isolation structures 17). Accordingly, a respective interfacial layer 212 surrounds semiconductor layer 26U, a respective interfacial layer 212 surrounds semiconductor layer 26L, a respective interfacial layer 212 wraps mesa 14′, and respective interfacial layers 212 wrap semiconductor layers 26M. In the X—Z cross-sectional view (e.g., FIG. 1A), interfacial layers 212 may cover top and bottom of semiconductor layer 26U, top and bottom of semiconductor layer 26L, top of upper semiconductor layer 26M, bottom of lower semiconductor layer 26M, and top of mesa 14′. Interfacial layers 212 include a dielectric material, such as SiO₂, SiGeOₓ, HfSiO, SiON, other dielectric material, or a combination thereof. In some embodiments, interfacial layers 212 are group IV-based oxide layers, which generally refer to oxides of a group IV-based material (i.e., a material that includes at least one group IV element, such as Si, Ge, C, etc.). In some embodiments, interfacial layers 212 are group III-V-based oxide layers, which generally refer to oxides of a group III-V-based material (i.e., a material that includes at least one group III element, such as Al, Ga, In, B, etc., and at least one group V element, such as N, P, As, Sb, etc.). In some embodiments, interfacial layers 212 have a substantially uniform thickness, such as depicted.

Referring to FIG. 2 and FIG. 3D, method 100 at block 130 includes forming high-k dielectric layers 215 over the upper channel structure (e.g., semiconductor layer 26U) and the lower channel structure (e.g., semiconductor layers 26M). High-k gate dielectric layers 215 are formed over interfacial layers 212, partially fill gate opening 208, and partially fill gaps 210. High-k dielectric layers 215 are formed by ALD, CVD, physical vapor deposition (PVD), an oxide-based deposition process, other suitable process, or a combination thereof. In the depicted embodiment, a respective high-k dielectric layer 215 surrounds semiconductor layer 26U, a respective high-k dielectric layer 215 surrounds semiconductor layer 26L, and a respective high-k dielectric layer 215 wraps mesa 14′ and extends over tops of substrate isolation structures 28. Further, a respective high-k dielectric layer 215 surrounds the intermediate structure of the channel stack, such that the respective high-k dielectric layer 215 wraps upper semiconductor layer 26M, wraps lower semiconductor layer 26M, and extends along sidewalls of isolation structure 17. In the X—Z cross-sectional view (e.g., FIG. 1A), high-k dielectric layers 215 may cover top and bottom of semiconductor layer 26U, top and bottom of semiconductor layer 26L, top of upper semiconductor layer 26M, bottom of lower semiconductor layer 26M, and top of mesa 14′. In some embodiments, in the X—Z cross-sectional view, high-k dielectric layer 215 over a top of semiconductor layer 26U may have a u-shaped profile.

High-k dielectric layers 215 include a high-k dielectric material, which generally refers to dielectric materials having a dielectric constant that is greater than a dielectric constant of silicon dioxide (k≈3.9), such as HfO₂, HfSiO, HfSiO₄, HfSION, HfLaO, HfTaO, HfTIO, HfZrO, HfAlOₓ, ZrO, ZrO₂, ZrSiO₂, AlO, AlSiO, Al₂O₃, TIO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃P₄, HfO₂—Al₂O₃, other high-k dielectric material, or a combination thereof. In some embodiments, high-k dielectric layers 215 are hafnium-based oxide (e.g., HfOₓ, such as HfO₂) layers. In some embodiments, high-k dielectric layers 215 are aluminum-based oxide (e.g., AlOₓ, such as Al₂O₃) layers. In some embodiments, high-k dielectric layers 215 are lanthanum-based oxide (e.g., LaOₓ, such as La₂O₃) layers. In some embodiments, high-k dielectric layers 215 are zirconium-based oxide (e.g., ZrOₓ, such as ZrO₂) layers. In some embodiments, high-k dielectric layers 215 are zinc-based oxide (e.g., ZnOₓ) layers. In some embodiments, high-k dielectric layers 215 have multilayer structures. In some embodiments, high-k dielectric layers 215 have a substantially uniform thickness, such as depicted. In the depicted embodiment, a thickness of high-k dielectric layers 215 is greater than a thickness of interfacial layers 212.

Referring to FIG. 2 and FIG. 3E, method 100 at block 130 includes forming a dipole dopant source layer 220 over high-k dielectric layers 215. Dipole dopant source layer 220 partially fills gate opening 208 and partially fills gaps 210. Dipole dopant source layer 220 is formed by ALD, CVD, other suitable process, or a combination thereof. In the depicted embodiment, dipole dopant source layer 220 surrounds semiconductor layer 26U, surrounds semiconductor layer 26L, and wraps mesa 14′ and extends over tops of substrate isolation structures 28. Dipole dopant source layer 220 may further surround the intermediate structure of the channel stack. In the X—Z cross-sectional view (e.g., FIG. 1A), dipole dopant source layer 220 may cover top and bottom of semiconductor layer 26U, top and bottom of semiconductor layer 26L, top of upper semiconductor layer 26M, bottom of lower semiconductor layer 26M, and top of mesa 14′. In some embodiments, in the X—Z cross-sectional view, dipole dopant source layer 220 over a top of semiconductor layer 26U may have a u-shaped profile.

Dipole dopant source layer 220 is a dielectric layer that includes dipole dopant(s) that may be driven into high-k dielectric layers 215 to change a threshold voltage of transistor 20U and/or transistor 20L. For example, driving dipole dopant into high-k dielectric layers 215 may increase or decrease threshold voltages of transistor 20U and/or transistor 20L depending on transistor type (e.g., n-type or p-type) and dipole type (e.g., n-type or p-type). In some embodiments, dipole dopant source layer 220 includes n-dipole dopant (e.g., a metal) and oxygen, nitrogen, carbon, or a combination thereof (e.g., a non-metal). The n-dipole dopant may be lanthanum (La), yttrium (Y), lutetium (Lu), strontium (Sr), erbium (Er), magnesium (Mg), other suitable n-dipole dopant, or a combination thereof. In some embodiments, dipole dopant source layer 220 includes p-dipole dopant (e.g., a metal) and oxygen, nitrogen, carbon, or a combination thereof (e.g., a non-metal). The p-dipole dopant may be aluminum (Al), titanium (Ti), zinc (Zn), other suitable p-dipole dopant, or a combination thereof. In some embodiments, dipole dopant source layer 220 includes n-dipole dopant and p-dipole dopant. Dipole dopant source layer 220 may have a substantially uniform thickness, such as depicted.

In some embodiments, such as depicted in FIG. E, dipole dopant source layer 220 partially fills gaps 210. In such embodiments, a dummy layer 222 may be formed over dipole dopant source layer 220 that fills remainders of gaps 210. A composition of dummy layer 222 is different than a composition of dipole dopant source layer 220 and high-k dielectric layers 215 to enable selective removal/etching thereof. In some embodiments, dummy layer 222 includes a dielectric material that is different than a dielectric material of dipole dopant source layer 220 and a dielectric material of high-k dielectric layers 215. In some embodiments, where dipole dopant source layer 220 is thicker and fills remainders of gaps 210, method 100 may omit forming dummy layer 222 over dipole dopant source layer 220.

Referring to FIG. 2, FIG. 3F, and FIG. 3G, method 100 includes forming a dummy layer 230 over dipole dopant source layer 220. In some embodiments, dummy layer 230 is also formed over dummy layer 222. In FIG. 3G, dummy layer 230 partially fills gate opening 208, and dummy layer 230 covers the lower channel structure of the channel stack. That is, dummy layer 230 covers dipole dopant source layer 220 around the lower channel structure (e.g., semiconductor layer 26L) but leaves dipole dopant source layer 220 around the upper channel structure (e.g., semiconductor layer 26U) exposed for subsequent processing. A composition of dummy layer 230 is different than a composition of dipole dopant source layer 220 and a subsequently formed hard mask to enable selective removal/etching thereof. Further, a composition of dummy layer 230 prevents formation/deposition of the subsequently formed hard mask thereon. For example, dummy layer 230 is a dielectric material that includes silicon, oxygen, and one or more terminal functional groups F, which may be at a surface thereof. The one or more functional groups inhibit hard mask material (e.g., metal-and-nitrogen containing material) from forming/depositing on dummy layer 230. Functional groups F include an aryl group, a phenyl group, an alkyl group, or a combination thereof. The alkyl group may be —CH₃, —C₂H₅, other alkyl group, or a combination thereof. The dielectric material may further include carbon and/or hydrogen. In some embodiments, dummy layer 230 is a silicon oxide layer (e.g., an SiO layer) having the one or more functional groups F. In some embodiments, dummy layer 230 is a silicon oxycarbide layer (e.g., an SiOC layer) having the one or more functional groups F. In embodiments where dummy layer 230 includes carbon (e.g., where dummy layer 230 is an SiOC layer), a concentration of carbon in dummy layer 230 is greater than about 0 atomic percent (at %) and less than about 30 at % (i.e., 0 at %<C≤30 at %).

In FIG. 3F, method 100 at block 140 includes depositing dummy layer 230 over dipole dopant source layer 220. For example, a spin-on deposition process (also referred to as a spin coating) forms a spin-on dummy material 230′ over dipole dopant source layer 220. A height of spin-on dummy material 230′ is greater than a height of the channel stack. Spin-on dummy material 230′ may partially fill or fill a remainder of gate opening 208, and spin-on dummy material 230′ wraps the channel stack. Spin-on dummy material 230′ thus covers the upper channel structure, the intermediate structure, and the lower channel structure. Parameters of the spin-on deposition process are tuned to provide spin-on dummy material 230′ with a composition that inhibits formation of hard mask material (e.g., metal-and-nitrogen containing material) thereon. In some embodiments, the spin-on deposition process includes dispensing and/or applying a dummy precursor material over a top of stacked device structure 10 and rotating/spinning stacked device structure 10 to disperse and/or spread the dummy precursor material evenly over the top of stacked device structure 10. The dummy precursor material may include a solvent and one or more of the following silicon-and-oxygen containing chemical compounds I-V, each of which has terminal functional groups (e.g., R, R₁, R₂, R₃, or a combination thereof) that inhibit adsorption of metal-and-nitrogen containing precursors that may be implemented to subsequently form a hard mask (e.g., a metal nitride hard mask):

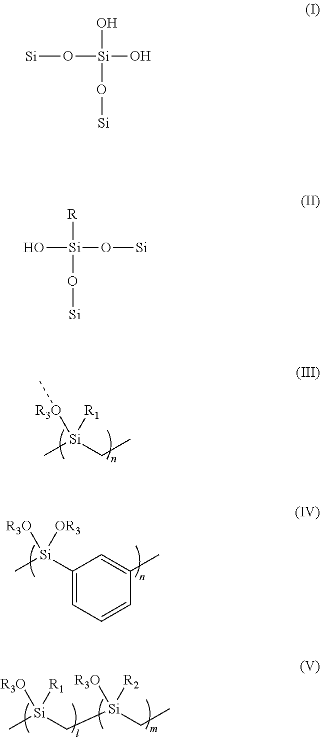

Each of R, R₁, R₂, and R₃ is an aryl group, a phenyl group, or an alkyl group. The alkyl group may have a carbon number between 1 and 10. The alkyl group may be —CH₃, —C₂H₅, or other alkyl group. In some embodiments, n is about 10 to about 20. In some embodiments, a ratio of 1 to m (1/m) is about 0.5 to about 0.95. In some embodiments, the dummy precursor material includes at least two of the silicon-and-oxygen containing compounds (e.g., two, three, four, or more). In some embodiments, the dummy precursor material is in liquid form.

As the dummy precursor material is spun and/or spread across stacked device structure 10, it may become spin-on dummy material 230′, which is a dielectric material that includes silicon, oxygen, and the one or more functional groups F. In some embodiments, the rotating/spinning of the spin-on deposition process includes a spin up stage and/or a spin off stage. The rotating/spinning may throw off excess dummy precursor material from stacked device structure 10 (e.g., ejected from edges of a wafer upon which stacked device structure 10 is fabricated). The dummy precursor material may be dispensed before or during rotating/spinning of stacked device structure 10. In some embodiments, the dummy precursor material is dispensed over a center of a wafer on which stacked device structure 10 is formed and the rotating/spinning spreads the dummy precursor material from the center to edges of the wafer. Parameters of the spin-on deposition process (e.g., spin speed, spin time, spin acceleration (e.g., from one spin speed to another), spin-on deposition temperature, flow rate and/or viscosity of the dummy precursor material, chemical compounds of the dummy precursor material, etc.) may be tuned to provide spin-on dummy material 230′ with a desired composition and/or a desired thickness. In some embodiments, the spin-on deposition process implements a spin speed of about 800 revolutions per minute (rpm) to about 2,000 rpm. In some embodiments, the spin-on deposition process implements various spin speeds. In some embodiments, the spin-on deposition process is performed for about 60 seconds to about 120 seconds. In some embodiments, the spin-on deposition process is performed at a temperature of about 250° C. to about 350° C. The solvent may evaporate upon dispensing of the dummy precursor material and/or during rotating/spinning of stacked device structure 10. In some embodiments, the spin-on deposition process includes an evaporation stage. For example, a baking process (e.g., a soft bake) may be performed after rotating/spinning the wafer. Parameters of the baking process (e.g., baking temperature, baking time, etc.) may be tuned to evaporate any remaining solvent. Other drying processes may also be implemented to evaporate any remaining solvent.

In FIG. 3G, method 100 at block 145 includes recessing dummy layer 230 to expose a portion of dipole dopant source layer 220 that covers high-k dielectric layers 215 over the upper channel structure (e.g., semiconductor layer 26U). The recessing may also expose a portion of dipole dopant source layer 220 that covers high-k dielectric layers 215 over a portion of the intermediate structure that is above isolation structure 17 (e.g., upper semiconductor layer 26M thereof). In some embodiments, such as depicted, dummy layer 222 over the upper channel structure is also removed, separately or by the recessing of dummy layer 230, to expose dipole dopant source layer 220. The recessing reduces a height of spin-on dummy material 230′, such that a top of dummy layer 230 is below the upper channel structure (e.g., semiconductor layer 26U). In some embodiments, a top of dummy layer 230 is also below the portion of the intermediate structure above isolation structure 17 (e.g., upper semiconductor layer 26M). The recessing may be an etching process that selectively removes dummy layer 230 with respect to dipole dopant source layer 220. For example, the etching process etches dummy layer 230 with no (or negligible) etching of dipole dopant source layer 220. An etchant of the etching process may etch dummy layer 230 (e.g., a dielectric material having a first composition, such as silicon oxide or silicon oxycarbide) at a higher rate than dipole dopant source layer 220 (e.g., a dielectric material having a second composition, such as metal oxide). In some embodiments, the etching process also selectively removes dummy layer 222 (e.g., a dielectric material having a third composition that is different than the first composition and the second composition) with respect to dipole dopant source layer 220. While most of exposed dummy layer 222 is removed, a portion of dummy layer 222 may remain between semiconductor layer 26U and upper semiconductor layer 26M. In some embodiments, dummy layer 222 is completely removed from the upper channel structure, and dummy layer 222 does not remain between semiconductor layer 26U and upper semiconductor layer 26M, which may reopen gap 210 therebetween. In some embodiments, the etching process that recesses dummy layer 230 also recesses dummy layer 222 (e.g., the same etchant may selectively remove dummy layer 230 and dummy layer 222). In some embodiments, a first etching process uses a first etchant to recess dummy layer 230 and a second etching process uses a second etchant to recess dummy layer 222. The etching process is a dry etch, a wet etch, other suitable etch, or a combination thereof.

Spin-on dummy material 230′ is recessed a distance d below a topmost high-k dielectric layer 215 of the upper channel structure. Distance d is greater than a total thickness of a top portion of the channel stack (i.e., a portion of the channel stack and high-k dielectric layers 215 thereon that is disposed above isolation structure 17). The total thickness of the top portion of the channel stack may be given by a sum of a thickness of topmost high-k dielectric layer 215 (e.g., a thickness of a respective high-k dielectric layer 215 over a top of semiconductor layer 26U), a total thickness of semiconductor layers 26 above isolation structure 17 (e.g., a sum of a thickness of semiconductor layer 26U and a thickness of upper semiconductor layer 26M), and a total spacing between semiconductor layers 26 above isolation structure 17 (e.g., spacing between semiconductor layer 26U and upper semiconductor layer 26M). Further, to ensure dummy layer 230 remains over the lower channel structure (e.g., semiconductor layer 26L), distance d is less than or equal to a sum a thickness of isolation structure 17 and the total thickness of the top portion of the channel stack. In some embodiments, distance d is about 10 nm to about 50 nm. In the depicted embodiment, distance d is greater than the total thickness of the top portion of the channel stack and less than the sum of the thickness of isolation structure 17 and the total thickness of the top portion of the channel stack, and dummy layer 230 exposes a portion of dipole dopant source layer 220 along sidewalls of isolation structure 17.

Referring to FIG. 2 and FIG. 3H, method 100 at block 150 includes trimming and/or removing exposed dipole dopant source layer 220. In some embodiments, an etching process selectively removes dipole dopant source layer 220 with respect to dummy layer 230 and high-k dielectric layers 215. For example, the etching process etches dipole dopant source layer 220 with no (or negligible) etching of dummy layer 230 and high-k dielectric layers 215. An etchant of the etching process may etch dipole dopant source layer 220 (e.g., dielectric material having the second composition, such as metal oxide) at a higher rate than dummy layer 230 (e.g., dielectric material having the first composition, such as silicon oxide or silicon oxycarbide) and high-k dielectric layers 215 (e.g., dielectric material having a fourth composition, such as a metal oxide different than the metal oxide of dipole dopant source layer 220). The etching process is a dry etch, a wet etch, other suitable etch, or a combination thereof. In some embodiments, the etching process may also selectively remove dipole dopant source layer 220 with respect to dummy layer 222, and dummy layer 222 may remain in the upper channel structure between semiconductor layer 26U and upper semiconductor layer 26M. In some embodiments, the etching process may also remove dummy layer 222, such that dummy layer 222 between semiconductor layer 26U and upper semiconductor layer 26M does not remain after trimming dipole dopant source layer 220, which may reopen gap 210 therebetween.

Referring to FIG. 2 and FIG. 3I, method 100 at block 155 includes selectively forming a hard mask 240 over exposed high-k dielectric layers 215, such as high-k dielectric layers 215 over the upper channel structure (e.g., semiconductor layer 26U). Hard mask 240 may further be formed over high-k dielectric layers 215 over the intermediate structure of the channel stack (e.g., upper semiconductor layer 26M and a portion of isolation structure 17). In the depicted embodiment, hard mask 240 wraps the upper channel structure. In some embodiments, hard mask 240 partially or completely fills a gap between semiconductor layer 26U and semiconductor layer 26M, such that hard mask 240 may surround semiconductor layer 26U. A composition of hard mask 240 is different than a composition of dummy layer 230 and high-k dielectric layers 215 to enable (1) selective removal/etching and (2) selective deposition thereof. For example, hard mask 240 includes metal and nitrogen (e.g., a metal nitride layer). The metal may be titanium, aluminum, tantalum, other suitable metal, or a combination thereof. In some embodiments, hard mask 240 is a titanium nitride (TiN) layer. In some embodiments, hard mask 240 is an aluminum nitride (AlN) layer. In some embodiments, hard mask 240 is a tantalum nitride layer. In some embodiments, hard mask 240 has a multilayer structure. In some embodiments, hard mask 240 has a substantially uniform thickness, such as depicted. In some embodiments, a thickness of hard mask 240 is about 2 nm to about 4 nm.

A composition of hard mask 240 and a deposition process used to form hard mask 240 are tuned to inhibit deposition of hard mask material (e.g., metal-and-nitrogen containing material) on dummy layer 230. In other words, hard mask 240 forms/deposits on high-k dielectric layers 215 but not dummy layer 230. The deposition process may be ALD, PVD, CVD, other suitable deposition process, or a combination thereof. The deposition process may include flowing a deposition gas that includes a metal-containing precursor into a process chamber and tuning deposition parameters to selectively form/deposit hard mask material over high-k dielectric layers 215 (e.g., metal oxide) while limiting growth of the hard mask material over dummy layer 230 (e.g., silicon oxide or silicon oxycarbide). The metal-containing precursor may adsorb on metal oxide surfaces, but not silicon oxide surfaces and/or silicon oxycarbide surfaces. In some embodiments, the metal-containing precursor includes metal-containing chemical compounds having an alkyl group, a halogen group, or a combination thereof. The alkyl group may be —CH₃, —C₂H₆, other alkyl group, or a combination thereof. The halogen group may be —Cl and/or another halogen group. In some embodiments, the metal-containing precursor is TiCl₄. In some embodiments, the metal-containing precursor is Al(CH₃)₃. In some embodiments, the metal-containing precursor is TaN₅(C₂H₆)₅. Metal-containing precursors having an alkyl group, a halogen group, or a combination thereof (e.g., TiCl₄, Al(CH₃)₃, and TaN₅(C₂H₆)₅) do not easily adsorb on silicon-and-oxygen containing materials having the one or more functional groups F (i.e., dummy layer 230), which prevents hard mask 240 from forming on dummy layer 230. In some embodiments, a carrier gas delivers the metal-containing precursor and/or other precursor (e.g., N₂) to the process chamber. The carrier gas may be an inert gas, such as an argon-containing gas, a helium-containing gas, a xenon-containing gas, other suitable inert gas, or a combination thereof. Parameters of the deposition process (e.g., types of deposition precursors (e.g., type of metal-containing precursor), flow rates of the deposition precursors, deposition temperature, deposition time, deposition ambient, deposition pressure, deposition power (e.g., source power, RF bias power, etc.), deposition voltage (e.g., RF bias voltage), etc.) are tuned to facilitate selective deposition of hard mask 240. In some embodiments, a deposition temperature is about 250° C. to about 450° C.

Referring to FIG. 2 and FIG. 3J, method 100 at block 160 includes removing dummy layer 230. Hard mask 240 protects high-k dielectric layers 215 and/or the upper channel structure (e.g., semiconductor layer 26U) from damage during removal of dummy layer 230. For example, hard mask 240 prevents unintentional etching, and thus loss, of the upper channel structure and/or high-k dielectric layers 215 thereon, which has been observed to occur during removal of dummy layer 230 when the upper channel structure and/or high-k dielectric layers 215 thereon are unmasked. In some embodiments, an etching process selectively removes dummy layer 230 with respect to hard mask 240. For example, the etching process etches dummy layer 230 with no (or negligible) etching of hard mask 240. An etchant of the etching process may etch dummy layer 230 (e.g., dielectric material having the first composition, such as silicon oxide or silicon oxycarbide) at a higher rate than hard mask 240 (e.g., metal nitride). The etching process is a dry etch, a wet etch, other suitable etch, or a combination thereof. In some embodiments, the etching process also selectively removes dummy layer 222 (e.g., dielectric material having the third composition) with respect to dipole dopant source layer 220 (e.g., dielectric material having the second composition, such as metal oxide) and hard mask 240 (e.g., metal nitride). In some embodiments, the etching process that removes dummy layer 230 may also remove dummy layer 222 (e.g., the same etchant may selectively remove dummy layer 230 and dummy layer 222). In some embodiments, separate etching processes remove dummy layer 230 and dummy layer 222 (e.g., different etchants are used). In some embodiments, such as where dummy layer 222 does not cover dipole dopant source layer 220, the etching process may selectively remove dummy layer 230 with respect to dipole dopant source layer 220. For example, the etching process etches dummy layer 230 with no (or negligible) etching of dipole dopant source layer 220. In such example, an etchant of the etching process may etch dummy layer 230 (e.g., dielectric material having the first composition, such as silicon oxide or silicon oxycarbide) at a higher rate than dipole dopant source layer 220 (e.g., dielectric material having the second composition, such as metal oxide) and hard mask 240 (e.g., metal nitride).

Referring to FIG. 2 and FIG. 3K, method 100 at block 165 includes performing a dipole dopant drive-in process 245, such as a thermal drive-in process. Dipole dopant drive-in process 245 drives (diffuses) dipole dopant from dipole dopant source layer 220 into high-k dielectric layers 215 of the lower channel structure (e.g., semiconductor layer 26L). Dipole dopant drive-in process 245 may drive (diffuse) dipole dopant from dipole dopant source layer 220 into high-k dielectric layers 215 over a portion of the intermediate structure that is below isolation structure 17 (e.g., lower semiconductor layer 26M). Dipole dopant drive-in process 245 may be an annealing process, such as a rapid thermal annealing (RTA), a millisecond annealing (MSA), a microsecond annealing (μSA), a microwave annealing, a laser annealing, a spike annealing, a soak annealing, a furnace annealing, other suitable annealing process, or a combination thereof. Parameters of dipole dopant drive-in process 245 (e.g., drive-in temperature, time, ambient, pressure, etc.) are tuned to provide high-k dielectric layers 215 over the lower channel structure with desired dipole dopant concentrations and/or profiles. Thermal drive-in parameters, such as temperature, are selected to ensure dipole dopant drive-in process 245 does not adversely affect existing structures/features of stacked device structure 10 (e.g., prevent heat damage) and is yet sufficient to cause dipole dopant to migrate/diffuse into high-k dielectric layers 215 over the lower channel structure. In some embodiments, dipole dopant drive-in process 245 diffuses dipole dopant from dipole dopant source layer 220 to an interface between interfacial layers 210 and high-k dielectric layers 215 and/or into interfacial layers 210 over the lower channel structure and/or the portion of the intermediate structure.

Because dipole dopant is diffused into unmasked, lower high-k dielectric layers 215 having dipole dopant source layer 220 formed thereon but not into masked, upper high-k dielectric layers 215 that do not have dipole dopant source layer 220 formed thereon, lower high-k dielectric layers 215 become high-k dielectric layers 215L, and upper high-k dielectric layers 215 become high-k dielectric layers 215U. For example, high-k dielectric layers 215L are doped with dipole dopant, and high-k dielectric layers 215U are not doped with dipole dopant or have a lower concentration of dipole dopant than high-k dielectric layers 215L. Transistors of stacked device structure 10 are thus provided with different gate dielectrics (i.e., gate dielectrics having different compositions) that may adjust their threshold voltages relative to one another. For example, gate dielectric 78U of transistor 20U includes interfacial layers 212 and high-k dielectric layers 215U, and gate dielectric 78L of transistor 20L includes interfacial layers 212 and high-k dielectric layers 215L. In some embodiments, high-k dielectric layers 215L include a high-k dielectric metal, oxygen, and a dipole metal (e.g., from dipole dopant source layer 220), and high-k dielectric layers 215U include the high-k dielectric metal and oxygen. High-k dielectric layers 215U do not include the dipole metal (e.g., from dipole dopant source layer 220). In some embodiments, high-k dielectric layers 215U may further include a dipole metal that is different than the dipole metal of high-k dielectric layers 215L. For example, high-k dielectric layers 215U may include an n-dipole metal, and high-k dielectric layers 215L may include a p-dipole metal, or vice versa. In some embodiments, the dipole dopant is also diffused into interfacial layers 212 below isolation structure 17, such that the transistors may also have different interfacial layers (i.e., interfacial layers having different compositions). For example, interfacial layers 212 of gate dielectric 78L may include silicon, oxygen, and the dipole metal, while interfacial layers 212 of gate dielectric 78U may include silicon and oxygen, but no dipole metal from dipole dopant source layer 220. In some embodiments, a composition of masked, upper high-k dielectric layers 215 is not changed by dipole dopant drive-in process 245.

Referring to FIG. 2 and FIG. 3L, method 100 at block 170 includes removing a remainder of dipole dopant source layer 220, such as that disposed over the lower channel structure. Removing dipole dopant source layer 220 from between semiconductor layer 26L and lower semiconductor layer 26M and between semiconductor layer 26L and mesa 14′ reopens gaps 210 below isolation structure 17. Hard mask 240 may protect high-k dielectric layers 215U and/or the upper channel structure (e.g., semiconductor layer 26U) during removal of dipole dopant source layer 220. In some embodiments, an etching process selectively removes dipole dopant source layer 220 with respect to high-k dielectric layers 215L and hard mask 240. For example, the etching process etches dipole dopant source layer 220 with no (or negligible) etching of high-k dielectric layers 215L and hard mask 240. An etchant of the etching process may etch dipole dopant source layer 220 (e.g., dielectric material having the second composition, such as metal oxide) at a higher rate than high-k dielectric layers 215L (e.g., dielectric material having a fourth composition, such as metal oxide that is different than the metal oxide of dipole dopant source layer 220) and hard mask 240 (e.g., metal-and-nitrogen containing material). The etching process is a dry etch, a wet etch, other suitable etch, or a combination thereof.

Referring to FIG. 2, FIG. 3M, and FIG. 3N, method 100 at block 175 includes forming a lower gate electrode 250 over high-k dielectric layers 215L and over the lower channel structure (e.g., semiconductor layer 26L). Hard mask 240 may protect high-k dielectric layers 215U and/or the upper channel structure (e.g., semiconductor layer 26U) during formation of lower gate electrode 250. Lower gate electrode 250 partially fills gate opening 208 and fills remainders of gaps 210 below isolation structure 17 (e.g., gap 210 between semiconductor layer 26L and mesa 14′ and gap 210 between semiconductor layer 26L and lower semiconductor layer 26M). Lower gate electrode 250 surrounds the lower channel structure (e.g., semiconductor layer 26L) and provides gate electrode 80L of transistor 20L. Lower gate electrode 250 may wrap lower semiconductor layer 26M of the intermediate structure, extend along sidewalls of isolation structure 17 of the intermediate structure, and wrap a top of mesa 14′. In the X-Z plane (e.g., FIG. 1A), lower gate electrode 250 may cover top and bottom of semiconductor layer 26L, bottom of lower semiconductor layer 26M, and top of mesa 14′. Further, portions of lower gate electrode 250 may be surrounded by respective high-k dielectric layers 215L.

Lower gate electrode 250 includes at least one electrically conductive gate layer. In the depicted embodiment, the at least one electrically conductive gate layer of lower gate electrode 250 is a p-type work function metal (P-WFM) layer (also referred to as a p-metal layer). The p-type work function layer includes a p-type work function material, which generally refers to an electrically conductive material tuned to have a p-type work function. The p-type work function material may include a metal with a sufficiently high effective work function, such as titanium, tantalum, ruthenium, molybdenum, tungsten, palladium, platinum, iridium, other p-metal, alloys thereof, or a combination thereof. In some embodiments, the P-WFM layer is a titanium nitride layer, a molybdenum nitride layer, a palladium layer, a platinum layer, an iridium layer, a ruthenium layer, or a combination thereof. In some embodiments, the P-WFM layer has a multilayer structure (e.g., more than one P-WFM layer).

In some embodiments, the at least one electrically conductive gate layer of lower gate electrode 250 includes the P-WFM layer and a metal fill/bulk layer. The P-WFM layer is disposed over high-k dielectric layers 215L, and the metal fill/bulk layer is disposed over the P-WFM layer. The metal fill/bulk layer may include aluminum, tungsten, cobalt, copper, other suitable electrically conductive material, alloys thereof, or a combination thereof. In some embodiments, the at least one electrically conductive gate layer of lower gate electrode 250 includes the P-WFM layer, the metal fill/bulk layer, and additional gate electrode layers. The additional gate electrode layers may include a cap (e.g., a metal nitride cap and/or a silicon cap) over the P-WFM layer, a barrier layer (e.g., a metal nitride barrier layer) over the cap and/or the work function layer, other gate electrode layer, or a combination thereof.

In FIG. 3M, forming lower gate electrode 250 may include depositing a lower gate electrode material 250′ (e.g., a p-type work function material) over the channel stack by ALD, CVD, PVD, plating, other suitable process, or a combination thereof. A height of lower gate electrode material 250′ is greater than a height of the channel stack, in the depicted embodiment, such that lower gate electrode material 250′ wraps hard mask 240. In embodiments where lower gate electrode 250 includes more than one electrically conductive gate layer, lower gate electrode material 250′ includes more than one lower gate electrode material, and each lower gate electrode material may be deposited by a suitable process. For example, depositing lower gate electrode material 250′ may include depositing a work function layer over high-k dielectric layers 215L and hard mask 240, depositing a metal/fill bulk layer over the work function layer, depositing one or more electrically conductive gate layers (e.g., cap, barrier layer, etc.) over the work function layer and before forming the work function layer, or a combination thereof.

In FIG. 3N, forming lower gate electrode 250 may include recessing lower gate electrode material 250′ below the upper channel structure (e.g., semiconductor layer 26U), which removes lower gate electrode material 250′ from over hard mask 240. The recessing reduces a height of lower gate electrode material 250′, such that a top of lower gate electrode 250 is below the upper channel structure (e.g., semiconductor layer 26U). In the depicted embodiment, lower gate electrode 250 is below hard mask 240 after the recessing. In some embodiments, lower gate electrode material 250′ is recessed below the portion of the intermediate structure that is above isolation structure 17 (e.g., upper semiconductor layer 26M) and/or below a top of isolation structure 17, such as depicted. In some embodiments, an etching process selectively removes lower gate electrode material 250′ with respect to hard mask 240. For example, the etching process etches lower gate electrode material 250′ with no (or negligible) etching of hard mask 240. An etchant of the etching process may etch lower gate electrode material 250′ (e.g., metal-comprising material different than the metal-and-nitrogen comprising material of hard mask 240) at a higher rate than hard mask 240 (e.g., metal-and-nitrogen comprising material). The etching process is a dry etch, a wet etch, other suitable etch, or a combination thereof.

Referring to FIG. 2 and FIG. 3O, method 100 at block 180 includes removing hard mask 240. In the depicted embodiment, hard mask 240 functions to protect the upper channel structure (e.g., semiconductor layer 26U) and/or high-k dielectric layers 215U thereover during removal of dummy layer 230 and formation of lower gate electrode 250, and thus, hard mask 240 is removed after removing dummy layer 230 and forming lower gate electrode 250. In some embodiments, an etching process selectively removes hard mask 240 with respect to high-k dielectric layers 215U and lower gate electrode 250. For example, the etching process etches hard mask 240 with no (or negligible) etching of high-k dielectric layers 215U and lower gate electrode 250. An etchant of the etching process may etch hard mask 240 (e.g., metal-and-nitrogen containing material) at a higher rate than high-k dielectric layers 215U (e.g., dielectric material, such as metal oxide) and lower gate electrode 250 (e.g., metal-containing material that is different than the metal-and-nitrogen containing material of hard mask 240). The etching process is a dry etch, a wet etch, other suitable etch, or a combination thereof. For example, hard mask 240 is removed by a wet etch that uses a wet etchant that includes H₂O, NH₄OH, HCl, H₂O₂, other suitable wet etch chemicals, or a combination thereof. In some embodiments, the wet etchant may be a mixture of NH₄OH, H₂O₂, and H₂O (e.g., DIW). In some embodiments, removal of hard mask 240 is performed at a temperature of about 20° C. to about 75° C. In some embodiments, the etching process also selectively removes any remaining dummy layer 222 (e.g., dielectric material having the third composition) with respect to high-k dielectric layers 215U (e.g., dielectric material, such as metal oxide) and lower gate electrode 250. In some embodiments, the etching process that removes hard mask 240 may also remove dummy layer 222 (e.g., the same etchant may selectively remove hard mask 240 and dummy layer 222). In some embodiments, a first etching process uses a first etchant to remove hard mask 240 and a second etching process uses a second etchant to remove dummy layer 222.

Referring to FIG. 2 and FIG. 3P, method 100 at block 185 includes forming an upper gate electrode 260 over high-k dielectric layers 215U and over the upper channel structure (e.g., semiconductor layer 26U). Upper gate electrode 260 partially fills gate opening 208 and fills remainders of gaps 210 above isolation structure 17 (e.g., gap 210 between semiconductor layer 26U and upper semiconductor layer 26M). In some embodiments, upper gate electrode 260 fills a remainder of gate opening 208. Upper gate electrode 260 surrounds the upper channel structure (e.g., semiconductor layer 26U) and provides gate electrode 80U of transistor 20U. Upper gate electrode 260 may wrap upper semiconductor layer 26M of the intermediate structure and extend along sidewalls of isolation structure 17 of the intermediate structure. In the X-Z plane (e.g., FIG. 1A), upper gate electrode 260 may cover top and bottom of semiconductor layer 26U and top of upper semiconductor layer 26M. Further, a portion of upper gate electrode 260 below semiconductor layer 26U may be surrounded by a respective high-k dielectric layer 215U, and a portion of upper gate electrode 260 above semiconductor layer 26U may be wrapped by a respective one of high-k dielectric layers 215U having a u-shaped profile.

Upper gate electrode 260 includes at least one electrically conductive gate layer, and a configuration of upper gate electrode 260 may be different than a configuration of lower gate electrode 250. For example, in the depicted embodiment, the at least one electrically conductive gate layer of upper gate electrode 260 is an n-type work function metal (N-WFM) layer (also referred to as an n-metal layer), instead of a P-WFM layer. The n-type work function layer includes an n-type work function material, which generally refers to an electrically conductive material tuned to have an n-type work function. The n-type work function material may include a metal with a sufficiently low effective work function, such as aluminum, titanium, tantalum, zirconium, other n-metal, alloys thereof, or a combination thereof. In some embodiments, the N-WFM layer is a titanium aluminum layer, a titanium aluminum carbide layer, a tantalum layer, a tantalum aluminum layer, a tantalum aluminum carbide layer, or a combination thereof. In some embodiments, the N-WFM layer has a multilayer structure.

In some embodiments, the at least one electrically conductive gate layer of upper gate electrode 260 includes the N-WFM layer and a metal fill/bulk layer. The N-WFM layer is disposed over high-k dielectric layers 215U, and the metal fill/bulk layer is disposed over the N-WFM layer. The metal fill/bulk layer may include aluminum, tungsten, cobalt, copper, other suitable electrically conductive material, alloys thereof, or a combination thereof. In some embodiments, the at least one electrically conductive gate layer of upper gate electrode 260 includes the N-WFM layer, the metal fill/bulk layer, and additional gate electrode layers. The additional gate electrode layers may include a cap (e.g., a metal nitride cap and/or a silicon cap) over the N-WFM layer, a barrier layer (e.g., a metal nitride barrier layer) over the cap and/or the work function layer, other gate electrode layer, or a combination thereof.

Forming upper gate electrode 260 may include depositing an upper gate electrode material (e.g., an n-type work function material) over lower gate electrode 250 and the upper channel stack (e.g., semiconductor layer 26U) by ALD, CVD, PVD, plating, other suitable process, or a combination thereof. A thickness of upper gate electrode 260 is greater than the total thickness of the top portion of the channel stack, such that upper gate electrode 260 is disposed over a top of the channel stack. Further, the thickness of upper gate electrode 260 is greater than distance d. In embodiments where upper gate electrode 260 includes more than one electrically conductive gate layer, upper gate electrode material includes more than one upper gate electrode material, and each upper gate electrode material may be deposited by a suitable process. For example, depositing the upper gate electrode material may include depositing a work function layer over high-k dielectric layers 215U, depositing a metal/fill bulk layer over the work function layer, depositing one or more electrically conductive gate layers over the work function layer and before forming the work function layer, or a combination thereof. In some embodiments, a planarization process (e.g., CMP) may be performed to remove excess upper gate electrode material, such as that disposed over ILD layer 72U and/or CESL 72U.

Stacked device structure 10 thus provides a CFET having a first GAA transistor (e.g., transistor 20U, such as an n-type transistor) over a second GAA transistor (e.g., transistor 20L, such as a p-type transistor). Gate electrodes of the first GAA transistor and the second GAA transistor may include different work function materials, and gate dielectrics of the first GAA transistor and the second GAA transistor may have different compositions. For example, the first GAA transistor may include an N-WFM layer (which is or forms a portion of lower gate electrode 250) and a high-k dielectric layer doped with dipole dopant (e.g., high-k dielectric layer 215L), and the second GAA transistor may include a P-WFM layer (which is or forms a portion of upper gate electrode 260) and a high-k dielectric layer that is not doped with (or doped with a smaller concentration of) the dipole dopant (e.g., high-k dielectric layer 215U). In such embodiments, the first GAA transistor may be an n-type transistor, and the second GAA transistor may be a p-type transistor. The first GAA transistor may have a first threshold voltage, and the second GAA transistor may have a second threshold voltage. The second threshold voltage may be different than the first threshold voltage. In some embodiments, the first GAA transistor is a p-type transistor, the second GAA transistor is an n-type transistor, the first GAA transistor includes a P-WFM layer, instead of the N-WFM layer, and the second GAA transistors includes an N-WFM layer, instead of the P-WFM layer.

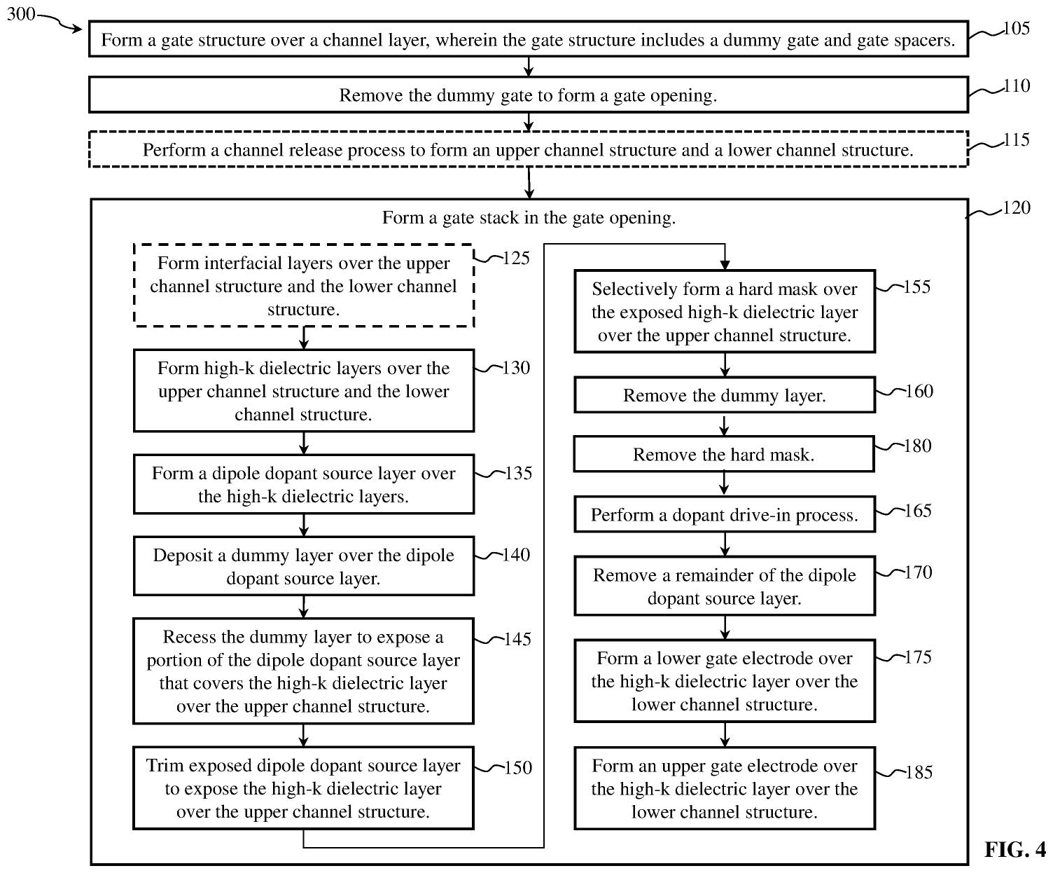

FIG. 4 is a flow chart of a method 300 for fabricating a gate stack of transistors of a transistor stack, such as gate 90 of the transistor stack of stacked device structure 10 of FIGS. 1A-IC, according to various aspects of the present disclosure. Method 300 is similar to method 100, except block 180 (e.g., removing the hard mask) is performed after removing dummy layer 130 at block 160 and before performing dipole dopant drive-in process 245 at block 165, instead of after forming lower gate electrode 250 at block 175. Since hard mask 240 functions to protect the upper channel structure (e.g., semiconductor layer 26U) and/or high-k dielectric layers 215 thereover during removal of dummy layer 230, hard mask 240 may be removed before gate electrode formation of stacked semiconductor structure 10. FIG. 4 has been simplified for the sake of clarity to better understand the inventive concepts of the present disclosure. Additional steps can be provided before, during, and after method 300, and some of the steps described can be moved, replaced, or eliminated for additional embodiments of method 300.

In method 300, at block 180, an etching process may selectively remove hard mask 240 with respect to dipole dopant source layer 220 and high-k dielectric layers 215. For example, the etching process etches hard mask 240 with no (or negligible) etching of dipole dopant source layer 220 and high-k dielectric layers 215. An etchant of the etching process may etch hard mask 240 (e.g., metal-and-nitrogen containing material) at a higher rate than dipole dopant source layer 220 (e.g., dielectric material, such as metal oxide) and high-k dielectric layers 215 (e.g., dielectric material, such as metal oxide different than the metal oxide of dipole dopant source layer 220). The etching process is a dry etch, a wet etch, other suitable etch, or a combination thereof. For example, hard mask 240 is removed by a wet etch that uses a wet etchant, which may be a mixture of NH₄OH, H₂O₂, and H₂O (e.g., DIW). In some embodiments, removal of hard mask 240 is performed at a temperature of about 20° C. to about 75° C.

Further, in method 300, at block 170, an etching process may selectively remove dipole dopant source layer 220 with respect to high-k dielectric layers 215L and high-k dielectric layers 215U. For example, the etching process etches dipole dopant source layer 220 with no (or negligible) etching of high-k dielectric layers 215L and high-k dielectric layers 215U. An etchant of the etching process may etch dipole dopant source layer 220 (e.g., dielectric material, such as metal oxide) at a higher rate than high-k dielectric layers 215L (e.g., dielectric material, such as metal oxide different than the metal oxide of dipole dopant source layer 220) and high-k dielectric layers 215U (e.g., dielectric material, such as metal oxide different than the metal oxide of dipole dopant source layer 220 and the metal oxide of high-k dielectric layers 215L). The etching process is a dry etch, a wet etch, other suitable etch, or a combination thereof.

Further, in method 300, at block 175, recessing lower gate electrode 250 may be achieved by an etching process that selectively removes lower gate electrode 250 with respect to high-k dielectric layers 215U. For example, the etching process etches lower gate electrode 250 with no (or negligible) etching of high-k dielectric layers 215U. An etchant of the etching process may etch lower gate electrode 250 (e.g., metal-containing material) at a higher rate than high-k dielectric layers 215U (e.g., dielectric material, such as metal oxide). The etching process is a dry etch, a wet etch, other suitable etch, or a combination thereof.

Devices and/or structures described herein, such as stacked device structure 10, device 12U, device 12L, transistor 20U, transistor 20L, etc. may be included in a microprocessor, a memory, other IC device, or a combination thereof. In some embodiments, stacked device structure 10 described herein is a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other components, or a combination thereof.

The present disclosure provides for many different embodiments. Gate stack (e.g., high-k/metal gate) fabrication methods are described herein and provide numerous advantages, particularly for stacked device structures. The gate stacks disclosed herein may be implemented in a variety of device types. For example, the gate stacks described herein are suitable for stacked planar field-effect transistors (FETs), stacked multigate transistors, such as stacked FinFETs, stacked GAA transistors, stacked fork-sheet devices, stacked omega-gate (Ω-gate) devices, stacked pi-gate (II-gate) devices, or a combination thereof.

An exemplary method includes forming a stacked channel structure that includes a first channel structure having a first gate dielectric disposed thereon, an isolation structure, and a second channel structure having a second gate dielectric disposed thereon. The second channel structure is disposed over the first channel structure, and the isolation structure is disposed between the first channel structure and the second channel structure. The method further includes forming a dummy layer having a top surface that is below the second channel structure and selectively depositing a hard mask over the second gate dielectric. Deposition parameters of the selectively depositing and a composition of the dummy layer are configured to inhibit deposition of the hard mask on the top surface of the dummy layer. The method further includes selectively removing the dummy layer and selectively removing the hard mask after selectively removing the dummy layer. The method may further include forming a first gate electrode over the first gate dielectric and forming a second gate electrode over the second gate dielectric. The hard mask is selectively removed before or after forming the first gate electrode.

In some embodiments, forming the dummy layer includes spin-coating a dielectric material over the stacked channel structure and recessing the dielectric material below the second channel structure. In such embodiments, after the spin-coating, a height of the dielectric material may be greater than a height of the stacked channel structure. In some embodiments, the hard mask is a metal nitride layer, and the composition of the dummy layer includes silicon, oxygen, and a terminal functional group that inhibits formation of the metal nitride layer on the dummy layer. The terminal functional group includes an aryl group, a phenyl group, an alkyl group, or a combination thereof. In some embodiments, the selectively depositing includes exposing the second gate dielectric and the dummy layer to a metal-containing precursor. The metal-containing precursor has an alkyl group, a halogen group, or a combination thereof. In some embodiments, the metal-containing precursor is TiCl₄, Al(CH₃)₃, or TaN₅(C₂H₆)₅.

Another exemplary method includes forming a channel stack over a substrate. The channel stack includes a first channel layer disposed over a second channel layer. The method further includes forming a first high-k dielectric layer around the first channel layer and a second high-k dielectric layer around the second channel layer. The method further includes performing a spin-on deposition process to form a dummy layer that wraps the channel stack. The dummy layer includes silicon, oxygen, and a terminal functional group that inhibits formation of metal nitride on the dummy layer. The method further includes recessing the dummy layer below the first channel layer, selectively depositing a metal nitride mask over the first high-k dielectric layer, and after selectively removing the dummy layer, selectively removing the metal nitride mask. In some embodiments, the spin-on deposition process includes dispensing a dummy precursor material over the substrate and rotating the substrate to spread the dummy precursor material over the substrate. The dummy precursor material includes one or more of the following silicon-and-oxygen containing chemical compounds I-V listed above.

In some embodiments, the method further includes forming a dipole dopant source layer over the first high-k dielectric layer and the second high-k dielectric layer before performing the spin-on deposition process. In such embodiments, after the spin-on deposition process to form the dummy layer and after the recessing of the dummy layer, the dummy layer covers a first portion of the dipole dopant source layer and exposes a second portion of the dipole dopant source layer. The first portion of the dipole dopant source layer is over the second high-k dielectric layer and the second portion of the dipole dopant source layer is over the first high-k dielectric layer. The method may further include selectively depositing the metal nitride mask over the first high-k dielectric layer after trimming the exposed second portion of the dipole dopant source layer and performing a dipole dopant drive-in process that drives a dipole dopant from the first portion of the dipole dopant source layer into the second high-k dielectric layer after selectively removing the dummy layer. The first portion of the dipole dopant source layer may be removed after performing the dipole dopant drive-in process. The metal nitride mask may be selectively removed before or after the dipole dopant drive-in process.

In some embodiments, selectively depositing the metal nitride mask includes exposing the second high-k dielectric layer and the dummy layer to a deposition gas that includes a metal-containing precursor having an alkyl group, a halogen group, or a combination thereof. In some embodiments, the metal-containing precursor includes titanium, aluminum, or tantalum, the alkyl group is —CH₃ or —C₂H₆, and the halogen group is —Cl.

Yet another exemplary method includes forming a first gate dielectric around a first channel layer of a first transistor of a transistor stack and a second gate dielectric around a second channel layer of a second transistor of the transistor stack. The second transistor is over the first transistor. The method further includes forming a dipole dopant source layer around the first channel layer and the second channel layer. The dipole dopant source layer is over the first gate dielectric and the second gate dielectric. The method further includes forming a dummy layer that covers a first portion of the dipole dopant source layer and exposes a second portion of the dipole dopant source layer. The first portion of the dipole dopant source layer is over the first gate dielectric, and the second portion of the dipole dopant source layer is over the second gate dielectric. The dummy layer includes silicon, oxygen, and a terminal functional group that inhibits formation of metal nitride on the dummy layer.

The method further includes removing the second portion of the dipole dopant source layer to expose the second gate dielectric around the second channel layer and forming a metal nitride mask over the exposed second gate dielectric. The metal nitride mask wraps the second channel layer. The method further includes removing the metal nitride mask after removing the dummy layer, performing a thermal drive-in process to drive dipole dopant from the first portion of the dipole dopant source layer into the first gate dielectric, and removing the first portion of the dipole dopant source layer. The method further includes forming a first gate electrode around the first channel layer and forming a second gate electrode around the second channel layer. The first gate electrode is over the first gate dielectric, and the second gate electrode is over the second gate dielectric. In some embodiments, the metal nitride mask is removed before forming the first gate electrode around the first channel layer. In some embodiments, the metal nitride mask is removed after forming the first gate electrode around the first channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stacked channel structure that includes a first channel structure having a first gate dielectric disposed thereon, an isolation structure, and a second channel structure having a second gate dielectric disposed thereon, wherein the second channel structure is disposed over the first channel structure and the isolation structure is disposed between the first channel structure and the second channel structure;
forming a dummy layer having a top surface that is below the second channel structure;
selectively depositing a hard mask over the second gate dielectric, wherein deposition parameters of the selectively depositing and a composition of the dummy layer are configured to inhibit deposition of the hard mask on the top surface of the dummy layer;
selectively removing the dummy layer; and
selectively removing the hard mask after selectively removing the dummy layer.

2. The method of claim 1, wherein the forming the dummy layer includes:
spin-coating a dielectric material over the stacked channel structure, wherein a height of the dielectric material is greater than a height of the stacked channel structure; and
recessing the dielectric material below the second channel structure.

3. The method of claim 1, wherein:
the hard mask is a metal nitride layer;
the composition of the dummy layer includes silicon, oxygen, and a terminal functional group that inhibits formation of the metal nitride layer on the dummy layer; and
wherein the terminal functional group includes an aryl group, a phenyl group, an alkyl group, or a combination thereof.

4. The method of claim 3, wherein the selectively depositing includes exposing the second gate dielectric and the dummy layer to a metal-containing precursor, wherein the metal-containing precursor has an alkyl group, a halogen group, or a combination thereof.

5. The method of claim 4, wherein the metal-containing precursor is TiCl₄.

6. The method of claim 4, wherein the metal-containing precursor is Al(CH₃)₃.

7. The method of claim 4, wherein the metal-containing precursor is TaN₅(C₂H₆)₅.

8. The method of claim 1, further comprising:
forming a first gate electrode over the first gate dielectric;
forming a second gate electrode over the second gate dielectric; and
wherein the hard mask is selectively removed before forming the first gate electrode.

9. The method of claim 1, further comprising:
forming a first gate electrode over the first gate dielectric;
forming a second gate electrode over the second gate dielectric; and
wherein the hard mask is selectively removed after forming the first gate electrode.

10. A method comprising:
forming a channel stack over a substrate, wherein the channel stack includes a first channel layer disposed over a second channel layer;
forming a first high-k dielectric layer around the first channel layer and a second high-k dielectric layer around the second channel layer;
performing a spin-on deposition process to form a dummy layer that wraps the channel stack, wherein the dummy layer includes silicon, oxygen, and a terminal functional group that inhibits formation of metal nitride on the dummy layer;
recessing the dummy layer below the first channel layer;
selectively depositing a metal nitride mask over the first high-k dielectric layer; and
after selectively removing the dummy layer, selectively removing the metal nitride mask.

11. The method of claim 10, further comprising forming a dipole dopant source layer over the first high-k dielectric layer and the second high-k dielectric layer before performing the spin-on deposition process;
wherein after the spin-on deposition process to form the dummy layer and after the recessing of the dummy layer, the dummy layer covers a first portion of the dipole dopant source layer and exposes a second portion of the dipole dopant source layer, wherein the first portion of the dipole dopant source layer is over the second high-k dielectric layer and the second portion of the dipole dopant source layer is over the first high-k dielectric layer;
after trimming the exposed second portion of the dipole dopant source layer, selectively depositing the metal nitride mask over the first high-k dielectric layer;
after selectively removing the dummy layer, performing a dipole dopant drive-in process that drives a dipole dopant from the first portion of the dipole dopant source layer into the second high-k dielectric layer; and
removing the first portion of the dipole dopant source layer.

12. The method of claim 11, further comprising selectively removing the metal nitride mask before the dipole dopant drive-in process.

13. The method of claim 11, further comprising selectively removing the metal nitride mask after the dipole dopant drive-in process.

14. The method of claim 10, wherein the selectively depositing the metal nitride mask includes exposing the second high-k dielectric layer and the dummy layer to a deposition gas that includes a metal-containing precursor, wherein the metal-containing precursor has an alkyl group, a halogen group, or a combination thereof.

15. The method of claim 14, wherein:
the metal-containing precursor includes titanium, aluminum, or tantalum;
the alkyl group is −CH₃ or —C₂H₆; and
the halogen group is —Cl.

16. The method of claim 10, wherein the spin-on deposition process includes dispensing a dummy precursor material over the substrate and rotating the substrate to spread the dummy precursor material over the substrate, wherein the dummy precursor material includes one or more of the following silicon-and-oxygen containing chemical compounds I-V: 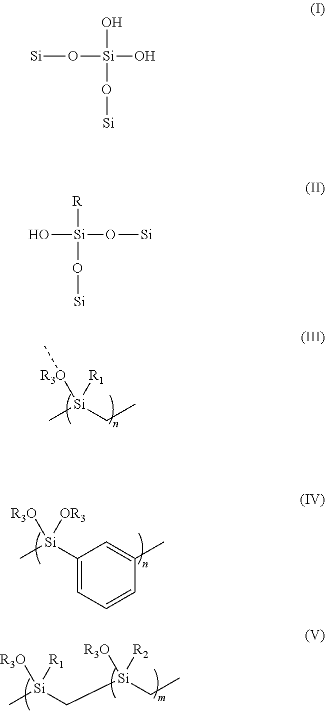
wherein each of R, R₁, R₂, and R₃ is a terminal functional group that inhibits adsorption of a metal-containing deposition precursor used to selectively deposit the metal nitride mask.

17. The method of claim 16, wherein:
each of R, R₁, R₂, and R₃ is an aryl group, a phenyl group, or an alkyl group;
the alkyl group has a carbon number between 1 and 10;
n is about 10 to about 20; and
a ratio of 1 to m (l/m) is about 0.5 to about 0.95.

18. A method comprising:
forming a first gate dielectric around a first channel layer of a first transistor of a transistor stack and a second gate dielectric around a second channel layer of a second transistor of the transistor stack, wherein the second transistor is over the first transistor;
forming a dipole dopant source layer around the first channel layer and the second channel layer, wherein the dipole dopant source layer is over the first gate dielectric and the dipole dopant source layer is over the second gate dielectric;
forming a dummy layer that covers a first portion of the dipole dopant source layer and exposes a second portion of the dipole dopant source layer, wherein the first portion of the dipole dopant source layer is over the first gate dielectric, the second portion of the dipole dopant source layer is over the second gate dielectric, and the dummy layer includes silicon, oxygen, and a terminal functional group that inhibits formation of metal nitride on the dummy layer;
removing the second portion of the dipole dopant source layer to expose the second gate dielectric around the second channel layer;
forming a metal nitride mask over the exposed second gate dielectric, wherein the metal nitride mask wraps the second channel layer;
after removing the dummy layer, removing the metal nitride mask;
performing a thermal drive-in process to drive dipole dopant from the first portion of the dipole dopant source layer into the first gate dielectric;
removing the first portion of the dipole dopant source layer;
forming a first gate electrode around the first channel layer, wherein the first gate electrode is over the first gate dielectric; and
forming a second gate electrode around the second channel layer, wherein the second gate electrode is over the second gate dielectric.

19. The method of claim 18, further comprising removing the metal nitride mask after forming the first gate electrode around the first channel layer.

20. The method of claim 18, further comprising removing the metal nitride mask before forming the first gate electrode around the first channel layer.
